(19) United States
(12) Patent Application Publication
(10) Pub. No.: US 2025/0374542 A1
(43) Pub. Date: Dec. 4, 2025

(54) MEMORY DEVICE INCLUDING SELF-ALIGNED DIELECTRIC BASE BELOW WORD LINE CONTACT VIA STRUCTURE AND METHOD FOR FORMING THE SAME

(71) Applicant: SANDISK TECHNOLOGIES LLC, ADDISON, TX (US)

(72) Inventors: Satoru TANAKA, Yokkaichi (JP); Wataru MURANAGA, Yokkaichi (JP); Takayuki MAEKURA, Yokkaichi (JP)

(21) Appl. No.: 18/675,721

(22) Filed: May 28, 2024

(51) Int. Cl. H10B 43/27; H01L 23/00; H01L 25/00; H01L 25/065; H01L 25/18; H10B 80/00

(52) U.S. Cl. CPC H10B 43/27; H01L 24/08; H01L 24/80; H01L 25/0657; H01L 25/18; H01L 25/50; H10B 80/00; H01L 2224/08145; H01L 2224/80006; H01L 2224/80895; H01L 2224/80896; H01L 2924/1431; H01L 2924/14511

(57) ABSTRACT

A memory device includes an alternating stack of insulating layers and electrically conductive layers, and having a staircase region, a vertical stack of memory elements vertically extending through the alternating stack, and a contact assembly. The contact assembly includes a layer contact via structure containing an upper portion and a lower portion having a smaller width than the upper portion, where the upper portion contacts a sidewall of an opening through a first electrically conductive layer of the electrically conductive layers in the staircase region, and the lower portion extends below the first electrically conductive layer, and a dielectric base containing a dielectric material and contacting an additional electrically conductive layer which underlies the first electrically conductive layer.

### FIELD

The present disclosure relates generally to the field of semiconductor devices, and particularly to a memory device including a self-aligned dielectric base below word line contact via structures and methods for manufacturing the same.

### BACKGROUND

Three-dimensional vertical NAND strings having one bit per cell are disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a memory device includes an alternating stack of insulating layers and electrically conductive layers, and having a staircase region, a vertical stack of memory elements vertically extending through the alternating stack, and a contact assembly. The contact assembly includes a layer contact via structure containing an upper portion and a lower portion having a smaller width than the upper portion, where the upper portion contacts a sidewall of an opening through a first electrically conductive layer of the electrically conductive layers in the staircase region, and the lower portion extends below the first electrically conductive layer, and a dielectric base containing a dielectric material and contacting an additional electrically conductive layer which underlies the first electrically conductive layer.

According to another aspect of the present disclosure, a method of forming a device structure is provided, which comprises: forming an alternating stack of insulating layers and spacer material layers over a substrate, wherein the spacer material layers are formed as, or are subsequently replaced with, electrically conductive layers; forming stepped surfaces by patterning the alternating stack, wherein lateral extents of the spacer material layer decrease with a vertical distance from a horizontal plane from the substrate; forming a retro-stepped dielectric material portion overlying the stepped surfaces; forming a layer contact via cavity through the retro-stepped dielectric material portion such that the layer contact via cavity vertically extends through a horizontally-extending surface segment of a stepped bottom surface of the retro-stepped dielectric material portion and through a first electrically conductive layer among the electrically conductive layers; forming a sacrificial tubular spacer in a peripheral volume of the layer contact via cavity; vertically extending the layer contact via cavity, wherein a vertically-extended portion of the layer contact via cavity extends at least through a first insulating layer among the insulating layers and into a second electrically conductive layer among the electrically conductive layers; performing a first isotropic etch process that etches a material of the electrically conductive layers selective to a material of the insulating layers, whereby a first fin cavity is formed in volumes from which an annular portion of the second electrically conductive layer is removed; forming a dielectric base within a volume of the first fin cavity and a predominant portion of the vertically-extended portion of the layer contact via cavity; and forming a layer contact via structure over the dielectric base on a physically exposed surface of the first electrically conductive layer.

### BRIEF DESCRIPTION OF THE DRAWINGS

FIG. 1 is a schematic vertical cross-sectional view of an exemplary structure after formation of an alternating stack of insulating layers and sacrificial material layers over a carrier substrate according to a first embodiment of the present disclosure.

FIG. 2 is a schematic vertical cross-sectional view of the exemplary structure after formation of stepped surfaces and a retro-stepped dielectric material portion according to an embodiment of the present disclosure.

FIG. 3A is a schematic vertical cross-sectional view of the exemplary structure after formation of memory openings and support openings according to an embodiment of the present disclosure. FIG. 3B is a top-down view of the exemplary structure of FIG. 3A. The hinged vertical cross-sectional plane A-A′ is the cut plane of the vertical cross-sectional view of FIG. 3A.

FIG. 4 is a schematic vertical cross-sectional view of the exemplary structure after formation of sacrificial opening fill structures according to an embodiment of the present disclosure.

FIG. 5 is a vertical cross-sectional view of the exemplary structure after formation of support pillar structures according to an embodiment of the present disclosure.

FIG. 6 is a schematic vertical cross-sectional view of the exemplary structure after removal of sacrificial memory opening fill structures according to an embodiment of the present disclosure.

FIGS. 7A-7F are sequential vertical cross-sectional views of a memory opening

during formation of a memory opening fill structure according to an embodiments of the present disclosure.

FIG. 8A is a schematic vertical cross-sectional view of the exemplary structure after formation of memory opening fill structures according to an embodiment of the present disclosure. FIG. 8B is a top-down view of the exemplary structure of FIG. 8A. The vertical plane A-A is the cut plane of the vertical cross-sectional view of FIG. 8A.

FIG. 9A is a vertical cross-sectional view of the exemplary structure after formation of a contact-level dielectric layer and lateral isolation trenches according to an embodiment of the present disclosure. FIG. 9B is a top-down view of the exemplary structure of FIG. 9A. The vertical plane A-A is the cut plane of the vertical cross-sectional view of FIG. 9A.

FIG. 10 is a vertical cross-sectional view of the exemplary structure after formation of laterally-extending cavities according to an embodiment of the present disclosure.

FIG. 11 is a schematic vertical cross-sectional view of the exemplary structure after formation of electrically conductive layers according to an embodiment of the present disclosure.

FIG. 12A is a vertical cross-sectional view of the exemplary structure after formation of lateral isolation trench fill structures and drain-select-level isolation structures according to an embodiment of the present disclosure. FIG. 12B is a top-down view of the exemplary structure of FIG. 12A. The hinged vertical cross-sectional plane A-A′ in FIG. 12B is the cut plane of the vertical cross-sectional view of FIG. 12A.

FIG. 13A is a vertical cross-sectional view of the exemplary structure after formation of layer contact via cavities according to an embodiment of the present disclosure. FIG. 13B is a top-down view of the exemplary structure of FIG. 13A. The hinged vertical cross-sectional plane A-A′ in FIG. 13B is the cut plane of the vertical cross-sectional view of FIG. 13A.

FIGS. 14A-14H are sequential vertical cross-sectional views of a region of the exemplary structure during expansion of the contact via cavities and formation of self-aligned dielectric bases according to an embodiment of the present disclosure.

FIGS. 14H and 14I are vertical cross-sectional views of regions of alternative embodiments of the exemplary structure after formation of self-aligned dielectric bases according to an embodiment of the present disclosure.

FIG. 15 is a vertical cross-sectional view of the exemplary structure after formation of the self-aligned dielectric bases according to an embodiment of the present disclosure.

FIG. 16 is a vertical cross-sectional view of the exemplary structure after formation of the drain contact via cavities according to an embodiment of the present disclosure.

FIG. 17 is a vertical cross-sectional view of the exemplary structure after removal of a patterned photoresist layer according to an embodiment of the present disclosure.

FIG. 18A is a vertical cross-sectional view of the exemplary structure after formation of layer contact via structures according to an embodiment of the present disclosure. FIG. 18B is a top-down view of the exemplary structure of FIG. 18A. The hinged vertical cross-sectional plane A-A′ in FIG. 18B is the cut plane of the vertical cross-sectional view of FIG. 18A. FIG. 18C is a vertical cross-sectional view of a region of the exemplary structure of FIGS. 18A and 18B. FIGS. 18D and 18E are vertical cross-sectional views of regions of the alternative embodiments of the exemplary structure of FIGS. 18A and 18B.

FIG. 19 is a vertical cross-sectional view of the exemplary structure after formation of a memory die according to an embodiment of the present disclosure.

FIG. 20 is a vertical cross-sectional view of a logic die according to an embodiment of the present disclosure.

FIG. 21 is a vertical cross-sectional view of the exemplary structure after attaching the logic die to the memory die according to an embodiment of the present disclosure.

FIG. 22 is a vertical cross-sectional view of the exemplary structure after removal of the carrier substrate according to an embodiment of the present disclosure.

FIG. 23 is a vertical cross-sectional view of the exemplary structure after formation of a source layer and backside contact structures according to an embodiment of the present

### DETAILED DESCRIPTION

Embodiments of the present disclosure are directed to a memory device including self-aligned dielectric bases located below respective word line contact via structures and methods for manufacturing the same. Embodiments of the disclosure can be employed to form various structures including a three-dimensional memory structure, non-limiting examples of which include three-dimensional NAND memory devices.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, an element located “on” a second element can be located on the exterior side of a surface of the second element or on the interior side of the second element. As used herein, an element is located “directly on” a second element if there exist a physical contact between a surface of the element and a surface of the second element. As used herein, an element is “electrically connected to” a second element if there exists a conductive path consisting of at least one conductive material between the element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

Generally, a semiconductor die, or a semiconductor package, can include a memory chip. Each semiconductor package contains one or more dies (for example one, two, or four). The die is the smallest unit that can independently execute commands or report status. Each die contains one or more planes (typically one or two). Identical, concurrent operations can take place on each plane, although with some restrictions. Each plane contains a number of blocks, which are the smallest unit that can be erased in a single erase operation. Each block contains a number of pages, which are the smallest unit that can be programmed, i.e., a smallest unit on which a read operation can be performed.

As used herein, a “semiconducting material” refers to a material having electrical conductivity in the range from 1×10⁻⁵ S/m to 1×10⁵ S/m. As used herein, a “semiconductor material” refers to a material having electrical conductivity in the range from 1×10⁻⁵ S/m to 1 S/m in the absence of electrical dopants therein, and is capable of producing a doped material having electrical conductivity in a range from 1 S/m to 1×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1×10⁵ S/m. As used herein, an “insulator material” or a “dielectric material” refers to a material having electrical conductivity less than 1×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1×10⁻⁵ S/m to 1×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

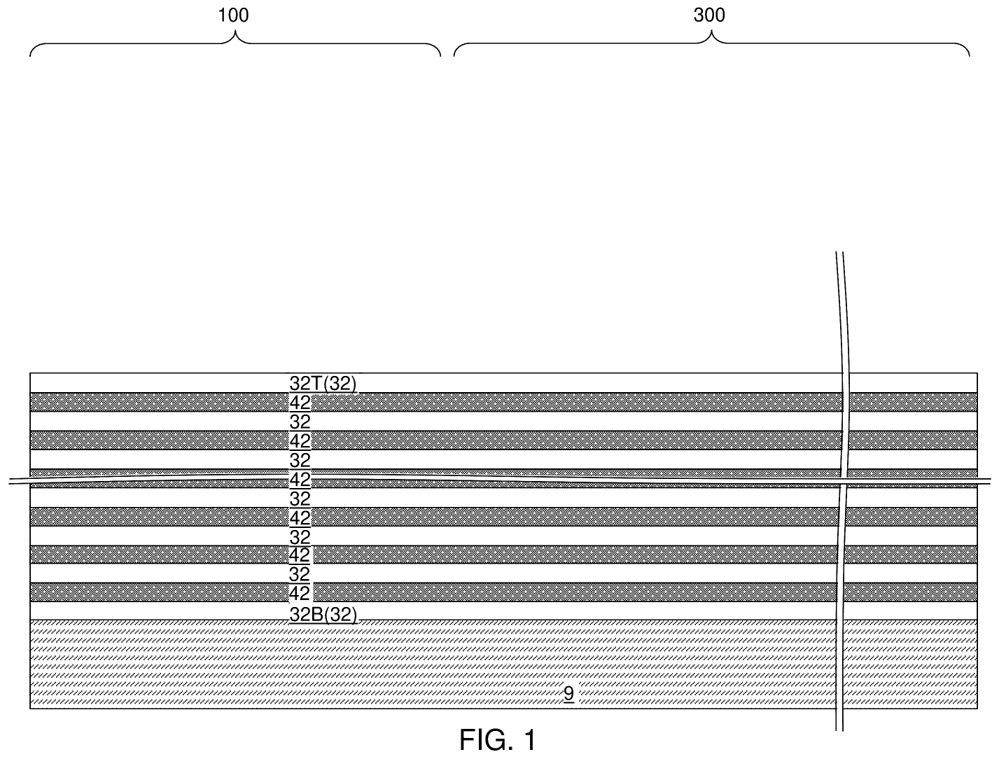

Referring to FIG. 1, an exemplary structure according to an embodiment of the present disclosure is illustrated. The exemplary structure comprises a carrier substrate 9, which may be a semiconductor substrate or a conductive substrate. For example, the carrier substrate 9 may comprise a commercially available silicon wafer. Alternatively, the carrier substrate 9 may comprise any material that may be removed selective to the materials of insulating layers 32 and dielectric material portions to be subsequently formed.

An alternating stack of first material layers and second material layers can be formed over the carrier substrate 9. The first material layers may be insulating layers, and the second material layers may be spacer material layers. In one embodiment, the spacer material layers may comprise sacrificial material layers 42. In this case, an alternating stack (32, 42) of insulating layers 32 and sacrificial material layers 42 can be formed over the carrier substrate 9. The insulating layers 32 comprise an insulating material such as undoped silicate glass or a doped silicate glass, and the sacrificial material layers 42 comprise a sacrificial material such as silicon nitride or a silicon-germanium alloy. In one embodiment, the insulating layers 32 (i.e., the first material layers) may comprise silicon oxide layers, and the sacrificial material layers 42 (i.e., the second material layers) may comprise silicon nitride layers.

The alternating stack (32, 42) may comprise multiple repetitions of a unit layer stack including an insulating layer 32 and a sacrificial material layer 42. The total number of repetitions of the unit layer stack within the alternating stack (32, 42) may be, for example, in a range from 8 to 1,024, such as from 32 to 256, although lesser and greater number of repetitions may also be employed. The topmost one of the insulating layers 32 is hereafter referred to as a topmost insulating layer 32T. The bottommost one of the insulating layers 32 (i.e., an insulating layer 32 that is most proximal to the carrier substrate 9) is herein referred to as a bottommost insulating layer 32B.

Each of the insulating layers 32 other than the topmost insulating layer 32T may have a thickness in a range from 20 nm to 100 nm, such as from 30 nm to 60 nm, although lesser and greater thicknesses may also be employed. Each of the sacrificial material layers 42 may have a thickness in a range from 20 nm to 100 nm, such as from 30 nm to 60 nm, although lesser and greater thicknesses may also be employed. In one embodiment, the topmost insulating layer 32T may have a thickness of about one half of the thickness of other insulating layers 32.

The exemplary structure comprises a memory array region 100 in which a three-dimensional array of memory elements is to be subsequently formed, and a contact region 300 in which layer contact via structures contacting word lines are to be subsequently formed.

While an embodiment is described in which the spacer material layers are formed as sacrificial material layers 42, the spacer material layers may be formed as electrically conductive layers in an alternative embodiment. Generally, spacer material layers of the present disclosure may be formed as, or may be subsequently replaced at least partly with, electrically conductive layers.

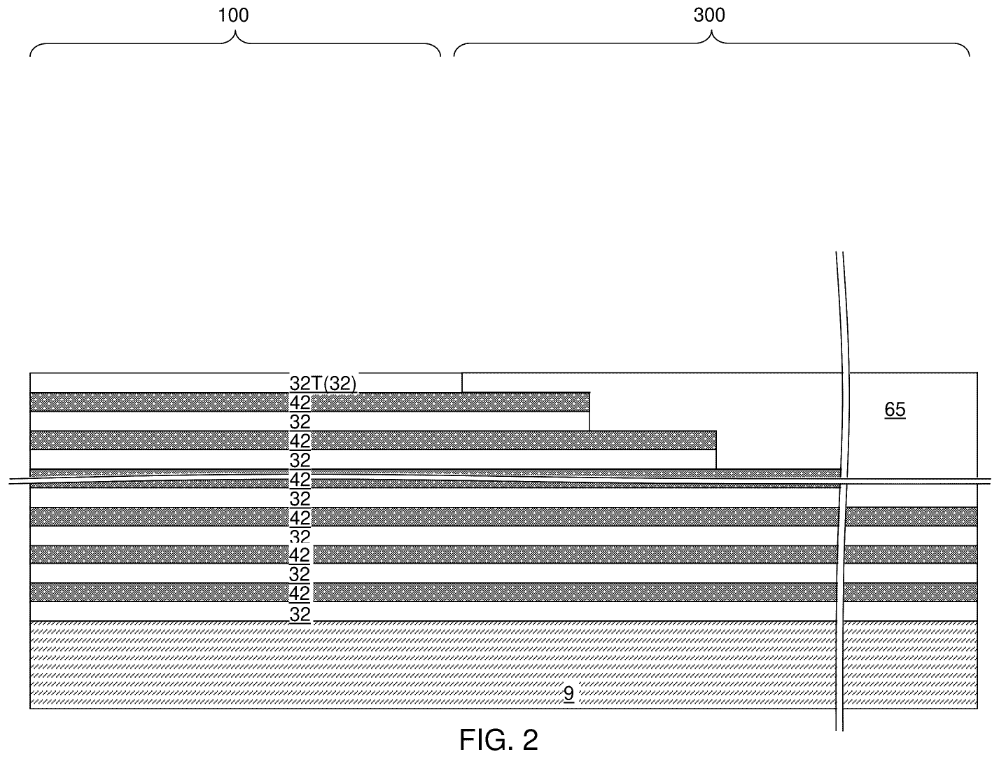

Referring to FIG. 2, optional stepped surfaces are formed in the contact region 300. As used herein, “stepped surfaces” refer to a set of surfaces that include at least two horizontal surfaces and at least two vertical surfaces such that each horizontal surface is adjoined to a first vertical surface that extends upward from a edge of the horizontal surface, and is adjoined to a second vertical surface that extends downward from a second edge of the horizontal surface. A stepped cavity is formed within the volume from which portions of the alternating stack (32, 42) are removed through formation of the stepped surfaces. A “stepped cavity” refers to a cavity having stepped surfaces.

The stepped cavity can have various stepped surfaces such that the horizontal cross-sectional shape of the stepped cavity changes in steps as a function of the vertical distance from the top surface of the carrier substrate 9. In one embodiment, the stepped cavity can be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type. As used herein, a “level” of a structure including alternating plurality is defined as the relative position of a pair of a first material layer and a second material layer within the structure.

Each sacrificial material layer 42 other than a topmost sacrificial material layer 42 within the alternating stack (32, 42) laterally extends farther than any overlying sacrificial material layer 42 within the alternating stack (32, 42) in the terrace region. The stepped surfaces of the alternating stack (32, 42) continuously extend from a bottommost layer within the alternating stack (32, 42) (such as the bottommost insulating layer 32B) to a topmost layer within the alternating stack (32, 42) (such as the topmost insulating layer 32T).

A retro-stepped dielectric material portion 65 (i.e., an insulating fill material portion) can be formed in the stepped cavity by deposition of a dielectric material therein. For example, a dielectric material such as silicon oxide can be deposited in the stepped cavity. Excess portions of the deposited dielectric material can be removed from above the top surface of the topmost insulating layer 32T, for example, by chemical mechanical planarization (CMP). The remaining portion of the deposited dielectric material filling the stepped cavity constitutes the retro-stepped dielectric material portion 65. As used herein, a “stepped” element refers to an element that has stepped surfaces and a horizontal cross-sectional area that increases or decreases stepwise as a function of a vertical distance from a top surface of a substrate on which the element is present. If silicon oxide is employed for the retro-stepped dielectric material portion 65, the silicon oxide of the retro-stepped dielectric material portion 65 may optionally be doped with dopants such as B, P, and/or F.

In summary, an alternating stack of insulating layers 32 and spacer material layers over a substrate such as a carrier substrate 9. The spacer material layers are formed as or are subsequently replaced with electrically conductive layers. Stepped surfaces are formed by patterning the alternating stack (32, 42). Lateral extents of the spacer material layer (such as the sacrificial material layers 42) vary with a vertical distance from a horizontal plane from the substrate. A retro-stepped dielectric material portion 65 can be formed over the stepped surfaces. The retro-stepped dielectric material portion 65 overlies the staircase region of the alternating stack and has a stepped bottom surface that contains horizontally-extending surface segments that are vertically offset from each other and adjoined to each other by vertically-extending surface segments.

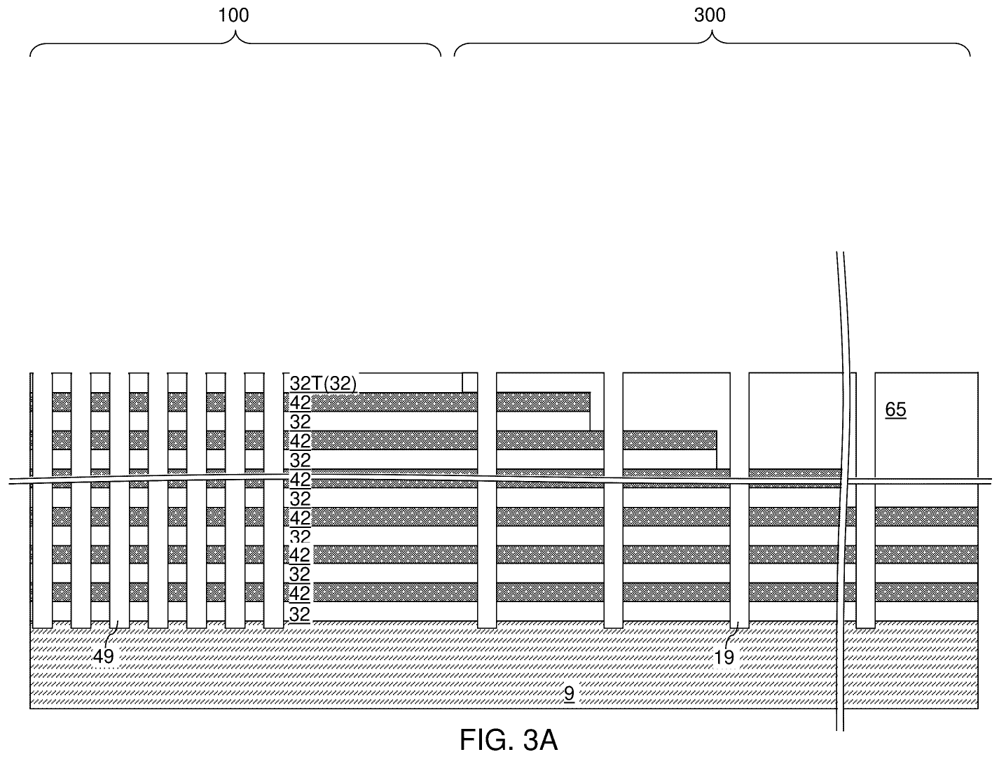

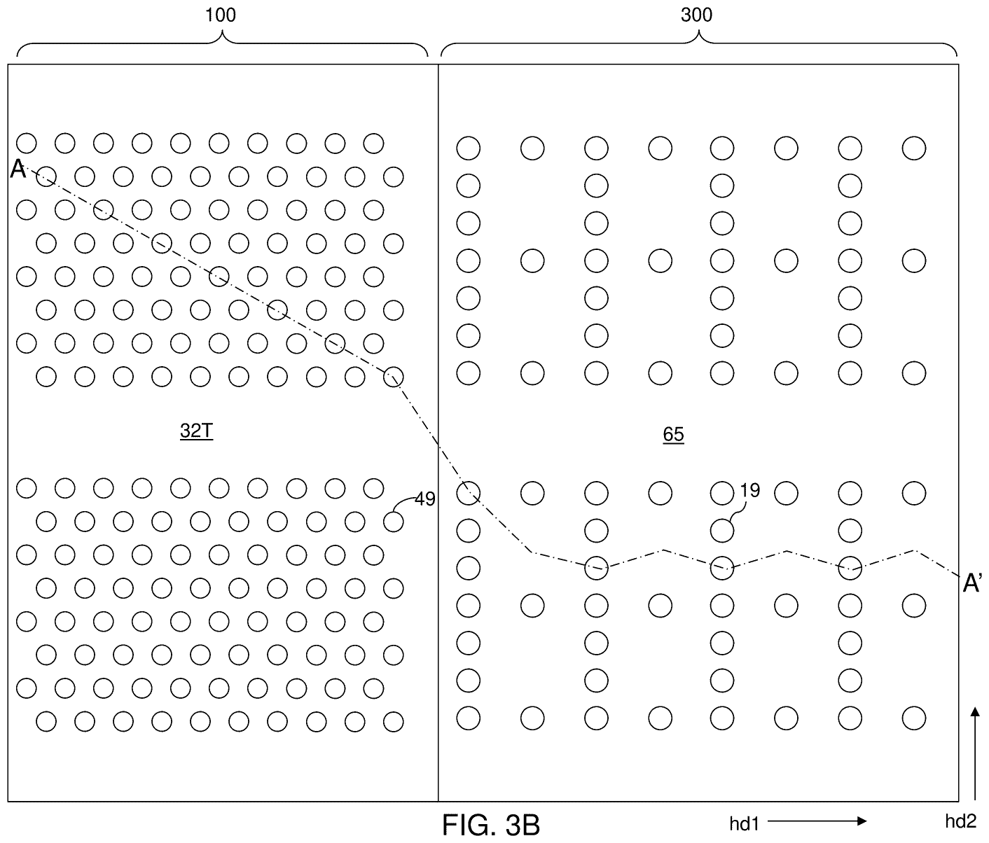

Referring to FIGS. 3A and 3B, an etch mask layer (such as a photoresist layer) can be formed over the alternating stack (32, 42), and can be lithographically patterned to form openings in the memory array region 100 and in the contact region 300. An anisotropic etch process can be performed to transfer the pattern of the openings in the etch mask layer through the retro-stepped dielectric material portion 65 and the alternating stack (32, 42). Memory openings 49 are formed through the alternating stack (32, 42) in the memory array region 100. Support openings 19 can optionally be formed through the retro-stepped dielectric material portion 65 and the alternating stack (32, 42) in the contact region 300.

Each of the memory openings 49 and the support openings 19 can vertically extend into the carrier substrate 9. In one embodiment, bottom surfaces of the memory openings 49 and the support openings 19 may be formed at or below the top surface of the carrier substrate 9. The memory openings 49 may have a diameter in a range from 60 nm to 400 nm, such as from 120 nm to 300 nm, although lesser and greater diameters may be employed. The support openings 19 may have a diameter in a range from 60 nm to 400 nm, such as from 120 nm to 300 nm, although lesser and greater diameters may be employed.

Each cluster of memory openings 49 (which corresponds to an area of a memory block) may comprise a plurality of rows of memory openings 49. Each row of memory openings 49 may comprise a plurality of memory openings 49 that are arranged along the first horizontal direction hd1 (which may be a word line direction) with a uniform pitch. The rows of memory openings 49 may be laterally spaced from each other along the second horizontal direction hd2 (which may be a bit line direction), which may be perpendicular to the first horizontal direction hd1. In one embodiment, each cluster of memory openings 49 may be formed as a two-dimensional periodic array of memory openings 49.

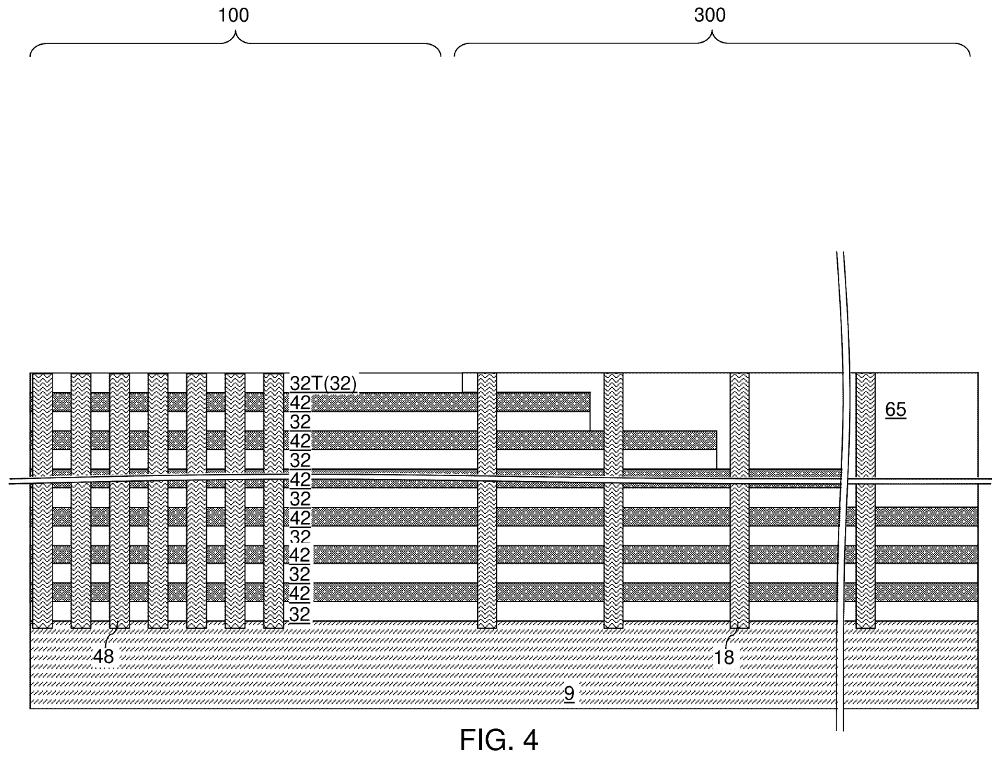

Referring to FIG. 4, an optional sacrificial liner layer (such as a thin silicon oxide layer) and a sacrificial fill material can be deposited in the memory openings 49 and in the support openings 19. The sacrificial fill material may comprise a carbon-based material (such as amorphous carbon or diamond-like carbon), a semiconductor material such as amorphous silicon or silicon-germanium), a polymer material, or a dielectric material (such as organosilicate glass or borosilicate glass). Excess portions of the sacrificial fill material may be removed from above the horizontal plane including the top surface of the topmost insulating layer 32T. Each remaining portion of the sacrificial fill material that fills a memory opening 49 constitutes a sacrificial memory opening fill structure 48. Each remaining portion of the sacrificial fill material that fills a support opening 19 constitutes a sacrificial support opening fill structure 18.

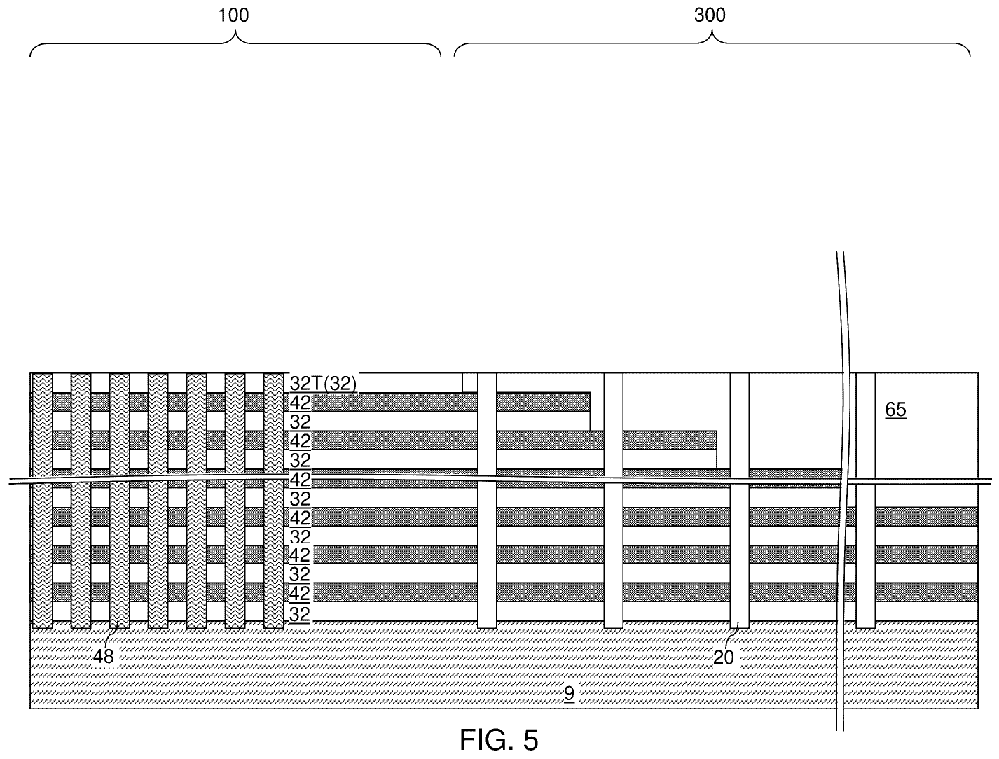

Referring to FIG. 5, a photoresist layer (not shown) can be applied over the exemplary structure, and can be lithographically patterned to cover the sacrificial memory opening fill structures 48 in the memory array region 100 without covering the sacrificial support opening fill structures 18 in the contact region 300. The sacrificial support opening fill structures 18 are subsequently removed selective to the materials of the insulating layers 32, the sacrificial material layers 42, and the carrier substrate 9 by ashing or selective etching. Voids are formed in the volumes of the support openings 19 from which the sacrificial support opening fill structures 18 are removed.

A dielectric fill material, such as silicon oxide, can be deposited in the support openings 19 by a conformal deposition process. Excess portions of the dielectric fill material can be removed from above the top surface of the topmost insulating layer 32T, for example, by a recess etch process. Each portion of the dielectric fill material that fills a respective support opening 19 constitutes a support pillar structure 20, which can be employed to provide structural support to the insulating layers 32 and the retro-stepped dielectric material portion 65 during replacement of the sacrificial material layers 42 with electrically conductive layers. Alternatively, the support openings 19 can be formed at a later step at the same time as the memory openings, and the support pillar structures 20 can be formed in the support openings 19 at the same time as the memory opening fill structures are formed in the memory openings, as will be described below.

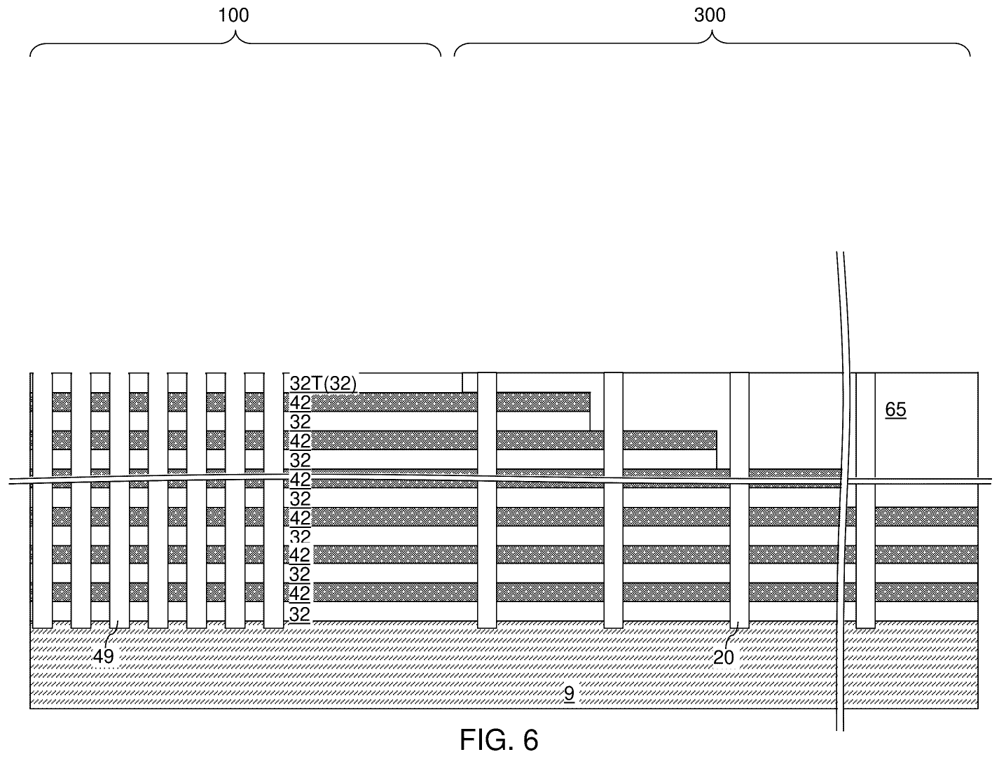

Referring to FIG. 6, sacrificial memory opening fill structures 48 are subsequently removed selective to the materials of the insulating layers 32, the sacrificial material layers 42, and the carrier substrate 9. Voids are formed in the volumes of the memory openings 49 from which the sacrificial memory opening fill structures 48 are removed.

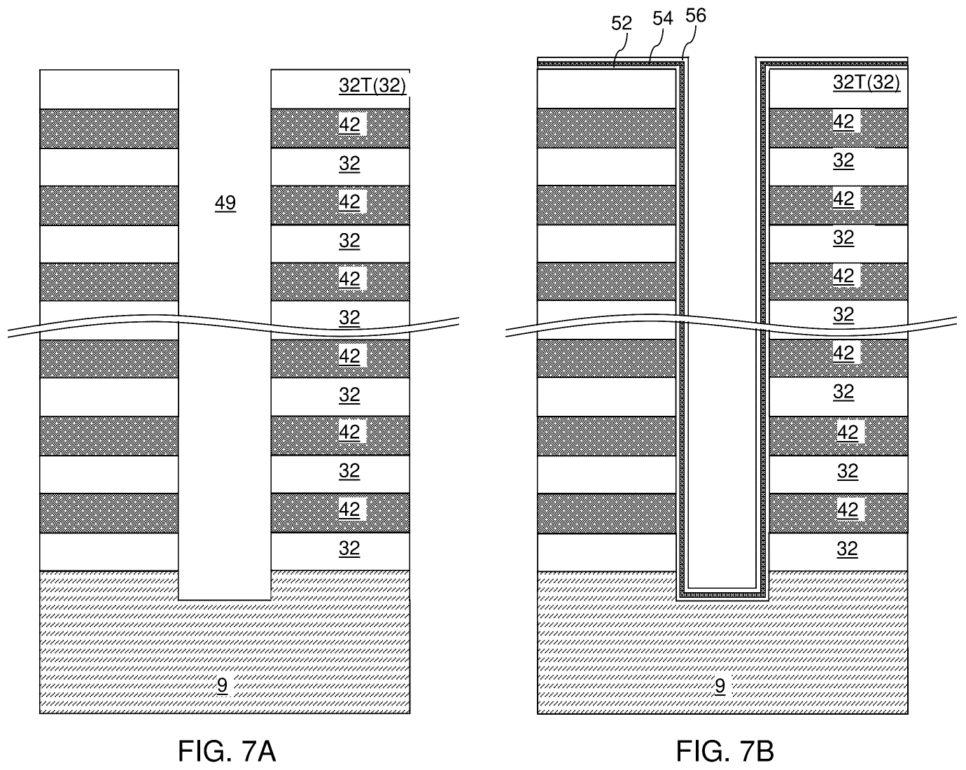

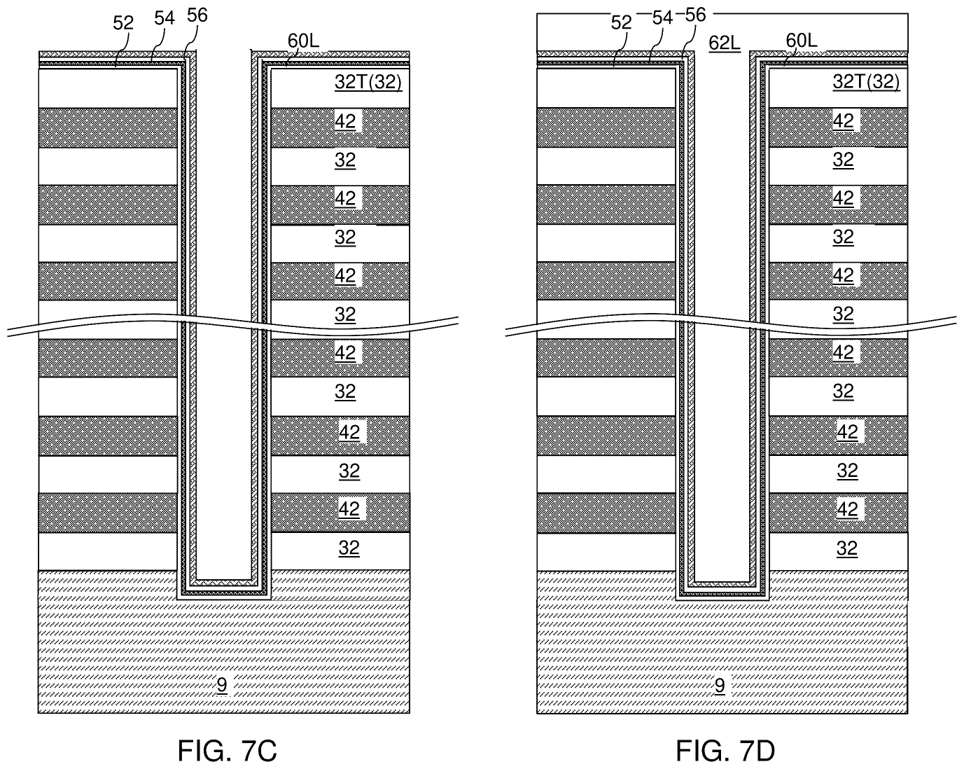

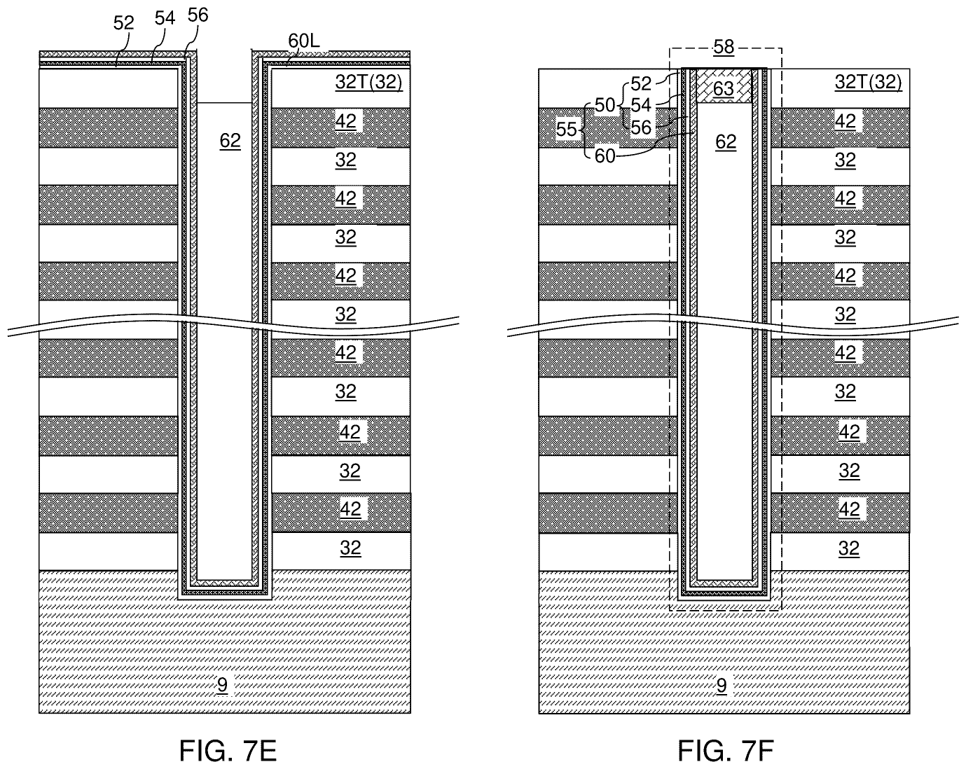

FIGS. 7A-7F are sequential vertical cross-sectional views of a memory opening 49 during formation of a memory opening fill structure 58 according to an embodiment of the present disclosure.

Referring to FIG. 7A, a memory opening 49 is illustrated after the processing steps of FIG. 6.

Referring to FIG. 7B, a layer stack including a memory material layer 54 can be conformally deposited. In an illustrative example, the layer stack may comprise an optional blocking dielectric layer 52, the memory material layer 54, and an optional dielectric liner 56. The memory material layer 54 includes a memory material, i.e., a material that can store data bits therein. The memory material layer 54 may comprise a charge storage material (such as silicon nitride), a ferroelectric material, a phase change memory material, or any other memory material that can store data bits by inducing a change in the electrical resistivity, ferroelectric polarization, or any other measurable physical property. In case the memory material layer 54 comprises a charge storage material, the optional dielectric liner 56 may comprise a tunneling dielectric layer.

Referring to FIG. 7C, a semiconductor channel material layer 60L can be deposited over the layer stack (52, 54, 56) by performing a conformal deposition process. If the semiconductor channel material layer 60L is doped, the semiconductor channel material layer 60L may have a doping of a first conductivity type, which may be p-type or n-type. The thickness of the semiconductor channel material layer 60L may be in a range from 5 nm to 50 nm, such as from 10 nm to 30 nm, although lesser and greater thicknesses may also be employed.

Referring to FIG. 7D, a dielectric core layer 62L comprising a dielectric fill material, such as silicon oxide, can be deposited in remaining volumes of the memory openings 49. The dielectric core layer 62L can be deposited employing a conformal deposition process, such as a chemical vapor deposition process.

Referring to FIG. 7E, the dielectric core layer 62L can be vertically recessed such that each remaining portion of the dielectric core layer has a top surface at, or about, the horizontal plane including the bottom surface of the topmost insulating layers 32. Each remaining portion of the dielectric core layer constitutes a dielectric core 62.

Referring to FIG. 7F, a doped semiconductor material having a doping of a second conductivity type can be deposited within each recessed region above the dielectric cores 62. The second conductivity type is the opposite of the first conductivity type. For example, if the first conductivity type is p-type, the second conductivity type is n-type, and vice versa. The dopant concentration in the deposited semiconductor material can be in a range from 5×10¹⁸/cm³ to 2×10²¹/cm³, although lesser and greater dopant concentrations can also be employed. The doped semiconductor material can be, for example, doped polysilicon.

Excess portions of the deposited semiconductor material having a doping of the second conductivity type and a horizontal portion of the semiconductor channel material layer 60L can be removed from above the horizontal plane including the top surface of the topmost insulating layer 32T, for example, by chemical mechanical planarization (CMP) or a recess etch process. Each remaining portion of the doped semiconductor material having a doping of the second conductivity type constitutes a drain region 63. Each remaining portion of the semiconductor channel material layer 60L (which has a doping of the first conductivity type) constitutes a vertical semiconductor channel 60.

Each portion of the layer stack including the memory material layer 54 that remains in a respective memory opening 49 constitutes a memory film 50. In one embodiment, a memory film 50 may comprise an optional blocking dielectric layer 52, a memory material layer 54, and an optional dielectric liner 56. Each contiguous combination of a memory film 50 and a vertical semiconductor channel 60 constitutes a memory stack structure 55. Each combination a memory stack structure 55, a dielectric core 62, and a drain region 63 within a memory opening 49 constitutes a memory opening fill structure 58. Each memory opening fill structure 58 comprises a respective vertical stack of memory elements, which may comprise portions of the memory material layer 54 located at levels of the sacrificial material layers 42, or generally speaking, at levels of spacer material layers that may be formed as, or may be subsequently replaced at least partly with, electrically conductive layers.

In the alternative embodiment, the support pillar structures 20 may be formed in the support openings 19 at the same time as the memory opening fill structures 58 are formed in the memory openings 49. In this case, the support pillar structures 20 comprise the same materials as the memory opening fill structures 58.

An anneal process can be performed to activate electrical dopants in the drain region 63 and in the vertical semiconductor channel 60. In this case, any amorphous semiconductor material in the vertical semiconductor channel 60 is converted into a polycrystalline semiconductor material. In one embodiment, grains within the vertical semiconductor channel 60 may extends predominantly along a respective local direction that is perpendicular to a respective proximal portion of an inner sidewall of the vertical semiconductor channel 60 and perpendicular to a respective proximal portion of an outer sidewall of the vertical semiconductor channel 60. As used herein, the grains extend predominantly along a specific direction if more than 50% of the drains extend along the specific direction.

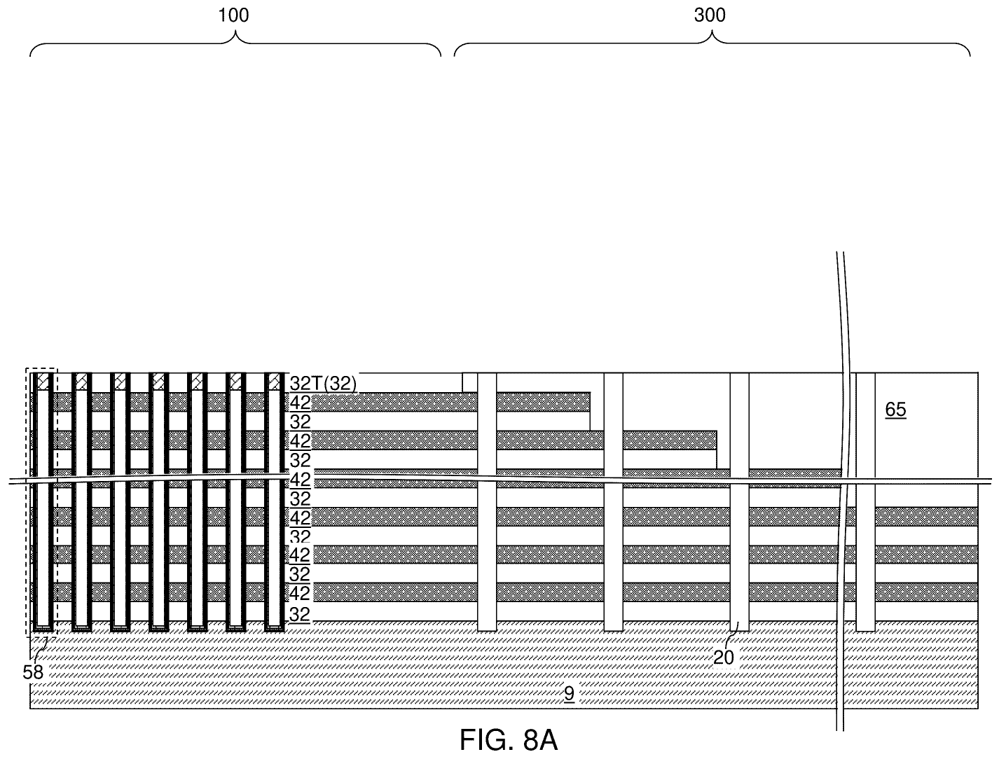

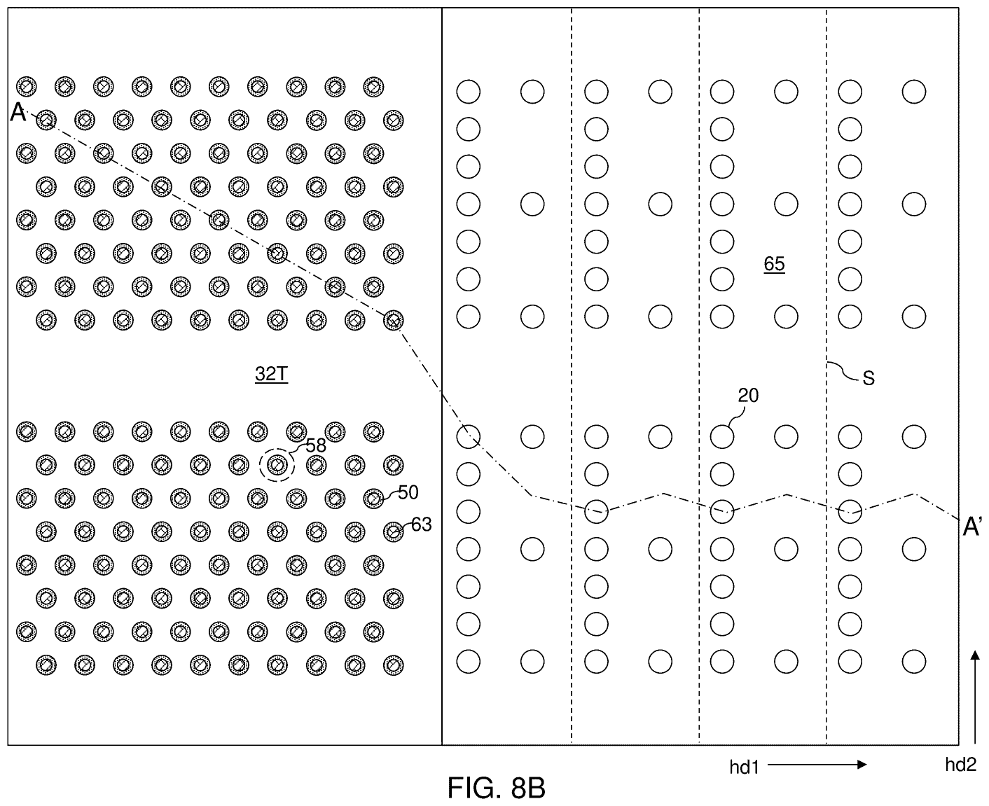

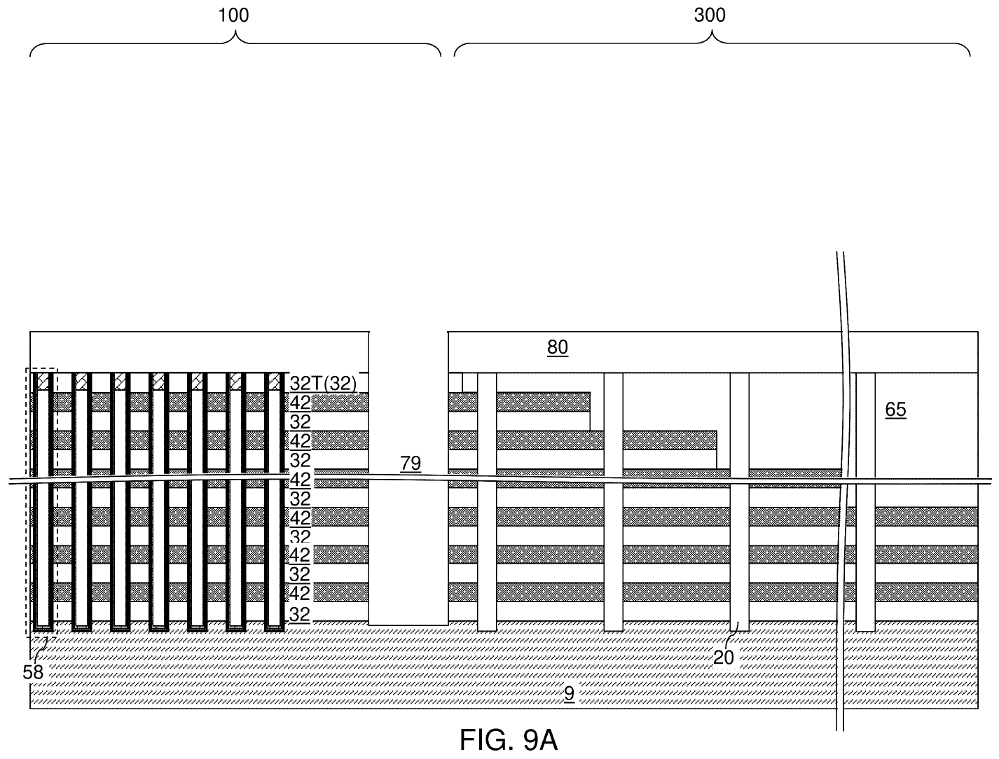

Referring to FIGS. 8A and 8B, the exemplary structure is illustrated after formation of memory opening fill structures 58 within the memory openings 49. The memory opening fill structures 58 are located in the memory openings 49. Each of the memory opening fill structures 58 comprises a respective memory film 50 and a respective vertical semiconductor channel 60.

Thus, an alternating stack (32, 42) of insulating layers 32 and sacrificial material layers 42 is formed over a substrate (such as a carrier substrate 9). The spacer material layers are formed as or are subsequently replaced with electrically conductive layers. Memory openings 49 are formed through the alternating stack (32, 42). Memory opening fill structures 58 are formed in the memory openings 49. Each of the memory opening fill structures 58 comprises a respective memory film 50 and a respective vertical semiconductor channel 60 that is laterally surrounded by the respective memory film 50. The memory opening fill structures 58 are arranged in rows laterally extending along a first horizontal direction hd1, and the rows are laterally spaced apart from each other along a second horizontal direction hd2 that is perpendicular to the first horizontal direction hd1. Each of the memory opening fill structures 58 comprises a vertical stack of memory elements (which may comprise portions of a memory film 50 located at levels of the sacrificial material layers 42), and a respective drain region 63.

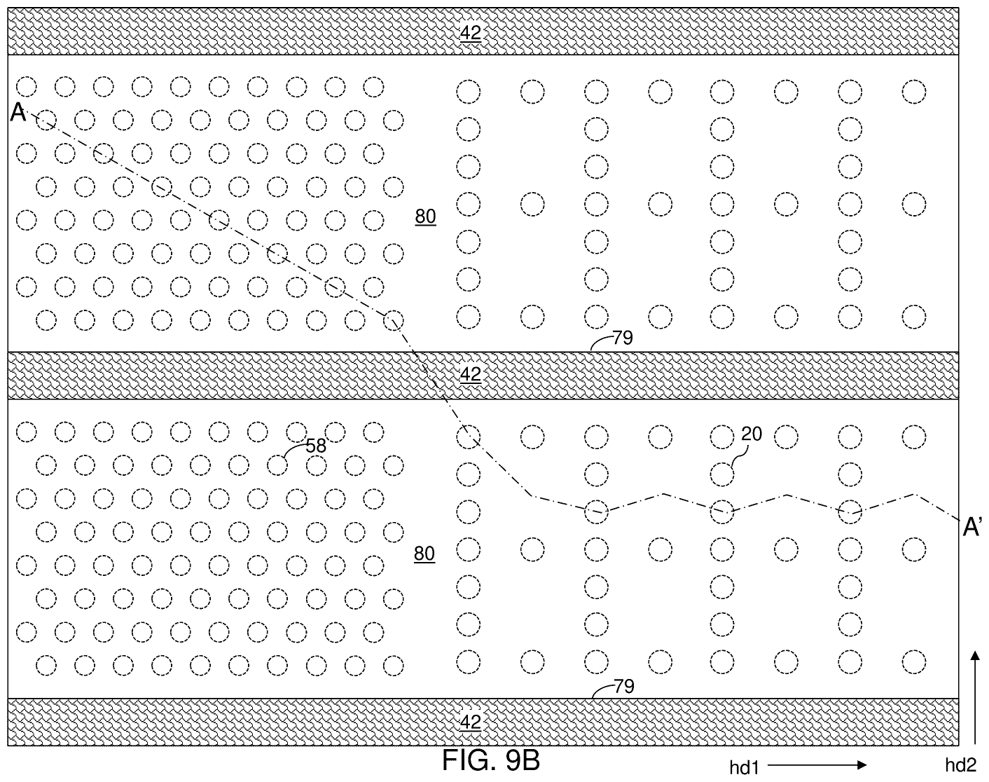

Referring to FIGS. 9A and 9B, a contact-level dielectric layer 80 can be formed over the alternating stack (32, 42), the memory opening fill structures 58, and the retro-stepped dielectric material portion 65. The contact-level dielectric layer 80 comprises a dielectric material, such as undoped silicate glass (i.e., silicon oxide) or a doped silicate glass. The thickness of the contact-level dielectric layer 80 may be in a range from 100 nm to 600 nm, such as from 200 nm to 400 nm, although lesser and greater thicknesses may also be employed.

A photoresist layer (not shown) can be applied over the contact-level dielectric layer 80, and can be lithographically patterned to form elongated openings that laterally extend along the first horizontal direction hd1 between neighboring clusters of memory opening fill structures 58. An anisotropic etch process can be performed to transfer the pattern of the openings in the photoresist layer through the contact-level dielectric layer 80, the alternating stack (32, 42), and the retro-stepped dielectric material portion 65, and to a top surface of the carrier substrate 9. Lateral isolation trenches 79 laterally extending along the first horizontal direction hd1 can be formed through the alternating stack (32, 42), the retro-stepped dielectric material portion 65, and the contact-level dielectric layer 80. Each of the lateral isolation trenches 79 may comprise a respective pair of lengthwise sidewalls that are parallel to the first horizontal direction hd1 and vertically extend from the top surface of the contact-level dielectric layer 80 to the top surface of the carrier substrate 9. A surface of the carrier substrate 9 can be physically exposed underneath each lateral isolation trench 79. The photoresist layer can be subsequently removed, for example, by ashing.

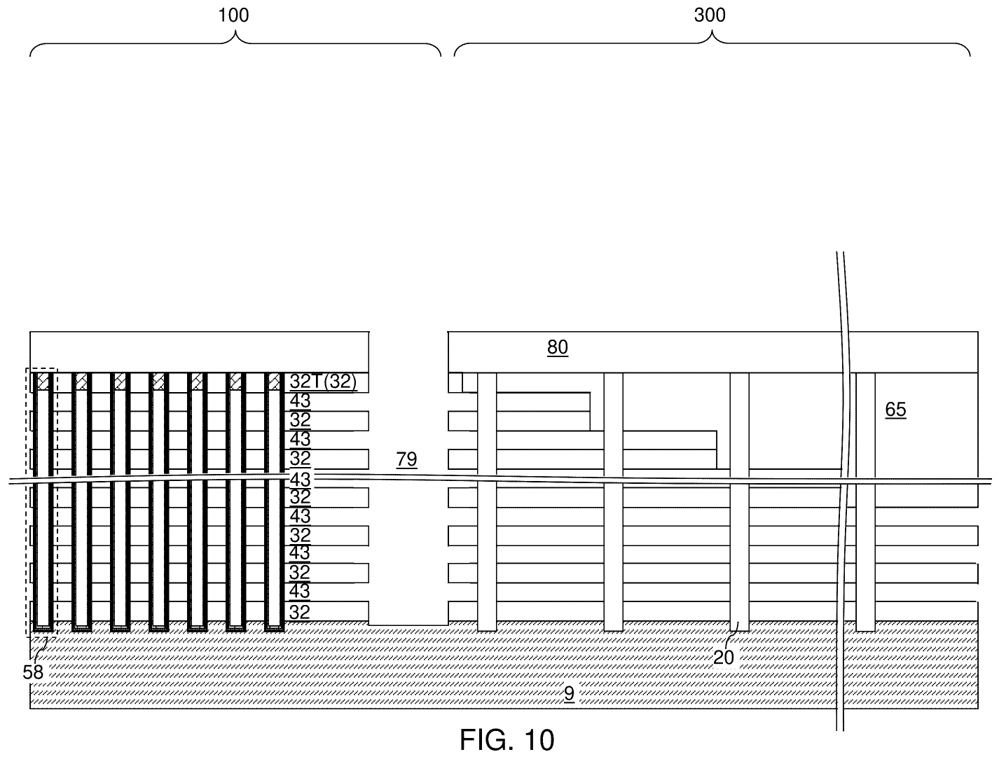

Referring to FIG. 10, an etchant that selectively etches the material of the sacrificial material layers 42 with respect to the material of the insulating layers 32, the contact-level dielectric layer 80 can be introduced into the lateral isolation trenches 79, for example, employing an isotropic etch process. Lateral recesses 43 are formed in volumes from which the sacrificial material layers 42 are removed. The removal of the sacrificial material layers 42 can be selective to the materials of the insulating layers 32, the contact-level dielectric layer 80, the retro-stepped dielectric material portion 65, and the material of the outermost layer of the memory films 50. In one embodiment, the sacrificial material layers 42 can include silicon nitride, and the materials of the insulating layers 32 and the retro-stepped dielectric material portion 65 can include silicon oxide.

The etch process that removes the second material selective to the first material and the outermost layer of the memory films 50 can be a wet etch process employing a wet etch solution, or can be a gas phase (dry) etch process in which the etchant is introduced in a vapor phase into the lateral isolation trenches 79. For example, if the sacrificial material layers 42 include silicon nitride, the etch process can be a wet etch process in which the exemplary structure is immersed within a wet etch tank including phosphoric acid, which etches silicon nitride selective to silicon oxide, silicon, and various other materials employed in the art. The support pillar structure 20, the retro-stepped dielectric material portion 65, and the memory stack structures 55 provide structural support while the lateral recesses 43 are present within volumes previously occupied by the sacrificial material layers 42.

Each lateral recess 43 can be a laterally extending cavity having a lateral dimension that is greater than the vertical extent of the cavity. In other words, the lateral dimension of each lateral recess 43 can be greater than the height of the lateral recess 43. A plurality of lateral recesses 43 can be formed in the volumes from which the second material of the sacrificial material layers 42 is removed.

Each of the plurality of lateral recesses 43 can extend substantially parallel to the top surface of the carrier substrate 9. A lateral recess 43 can be vertically bounded by a top surface of an underlying insulating layer 32 and a bottom surface of an overlying insulating layer 32. In one embodiment, each lateral recess 43 can have a uniform height throughout.

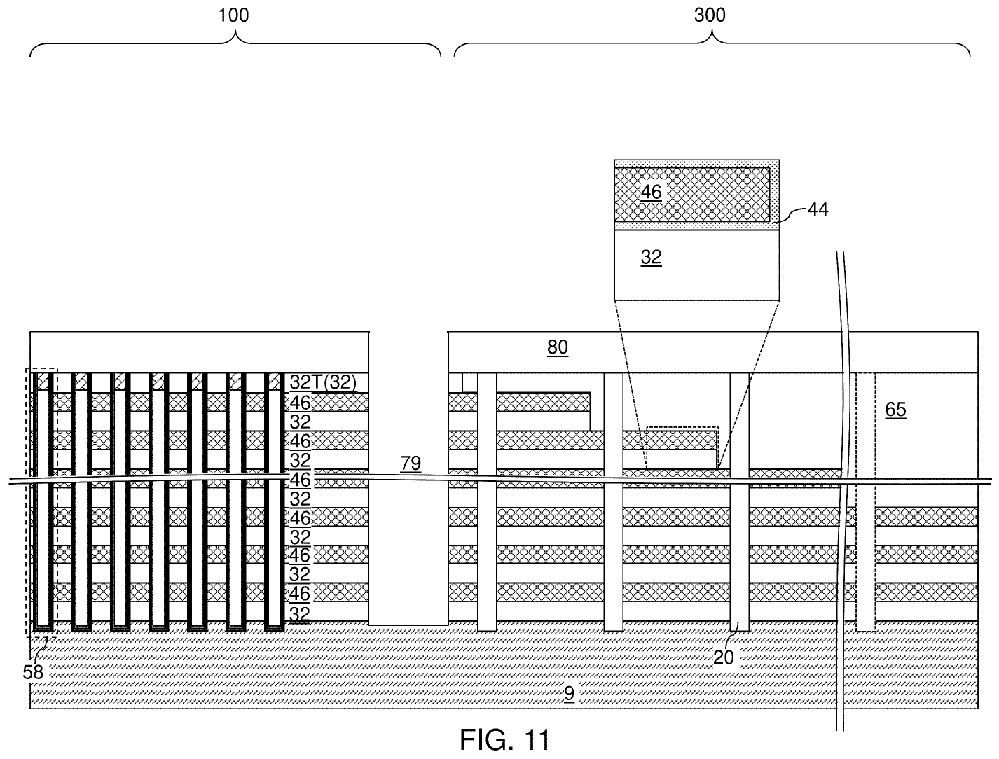

Referring to FIG. 11, an outer blocking dielectric layer 44 can be optionally formed. The outer blocking dielectric layer, if present, comprises a dielectric material that functions as a control gate dielectric for the control gates to be subsequently formed in the lateral recesses 43. In case the blocking dielectric layer 52 is present within each memory opening, the outer blocking dielectric layer is optional. In case the blocking dielectric layer 52 is omitted, the outer blocking dielectric layer is present.

At least one conductive material can be deposited in the lateral recesses 43 by providing at least one reactant gas into the lateral recesses 43 through the lateral isolation trenches 79. A metallic barrier layer can be deposited in the lateral recesses 43. The metallic barrier layer includes an electrically conductive metallic material that can function as a diffusion barrier layer and/or adhesion promotion layer for a metallic fill material to be subsequently deposited. The metallic barrier layer can include a conductive metallic nitride material such as TiN, TaN, WN, or a stack thereof, or can include a conductive metallic carbide material such as TiC, TaC, WC, or a stack thereof. In one embodiment, the metallic barrier layer can be deposited by a conformal deposition process such as chemical vapor deposition (CVD) or atomic layer deposition (ALD). The thickness of the metallic barrier layer can be in a range from 2 nm to 8 nm, such as from 3 nm to 6 nm, although lesser and greater thicknesses can also be employed. In one embodiment, the metallic barrier layer can consist essentially of a conductive metal nitride such as TiN.

A metal fill material is deposited in the plurality of lateral recesses 43, on the sidewalls of each lateral isolation trench 79, and over the top surface of the contact-level dielectric layer 80 to form a metallic fill material layer. The metallic fill material can be deposited by a conformal deposition method, which can be, for example, chemical vapor deposition (CVD), atomic layer deposition (ALD), electroless plating, electroplating, or a combination thereof. In one embodiment, the metallic fill material layer can consist essentially of at least one elemental metal. The at least one elemental metal of the metallic fill material layer can be selected, for example, from tungsten, cobalt, ruthenium, titanium, and tantalum. In one embodiment, the metallic fill material layer can consist essentially of a single elemental metal. In one embodiment, the metallic fill material layer can be deposited employing a fluorine-containing precursor gas such as WF₆. In one embodiment, the metallic fill material layer can be a tungsten layer including a residual level of fluorine atoms as impurities. The metallic fill material layer is spaced from the insulating layers 32 and the memory stack structures 55 by the metallic barrier layer, which is a metallic barrier layer that blocks diffusion of fluorine atoms therethrough.

A plurality of electrically conductive layers 46 can be formed in the plurality of lateral recesses 43, and a continuous metallic material layer can be formed on the sidewalls of each lateral isolation trench 79 and over the contact-level dielectric layer 80. Each electrically conductive layer 46 includes a portion of the metallic barrier layer and a portion of the metallic fill material layer that are located between a vertically neighboring pair of dielectric material layers such as a pair of insulating layers 32. The continuous metallic material layer includes a continuous portion of the metallic barrier layer and a continuous portion of the metallic fill material layer that are located in the lateral isolation trenches 79 or above the contact-level dielectric layer 80.

The deposited metallic material of the continuous electrically conductive material layer is etched back from the sidewalls of each lateral isolation trench 79 and from above the contact-level dielectric layer 80 by performing an isotropic etch process that etches the at least one conductive material of the continuous electrically conductive material layer. Each remaining portion of the deposited metallic material in the lateral recesses 43 constitutes an electrically conductive layer 46. Each electrically conductive layer 46 can be a conductive line structure. Thus, the sacrificial material layers 42 are replaced with the electrically conductive layers 46. Generally, the electrically conductive layers 46 can be formed by providing a metallic precursor gas into the lateral isolation trenches 79 and into the lateral recesses 43.

Each electrically conductive layer 46 may be embedded within a respective outer blocking dielectric layer 44, which may comprise a dielectric metal oxide material, such as aluminum oxide. Each outer blocking dielectric layer 44 may have a pair of horizontally-extending portions in contact with a respective one of the insulating layers 32, and a plurality of tubular portions laterally surrounding a respective one of the memory opening fill structures 58 and connecting the pair of horizontally-extending portions. The thickness of each outer blocking dielectric layer 44 may be in a range from 1 nm to 6 nm, although lesser and greater thicknesses may also be employed.

Generally, an assembly of an alternating stack (32, 46) and memory opening fill structures 58 can be formed. The alternating stack (32, 46) comprises a vertically alternating sequence of insulating layers 32 and electrically conductive layers 46. The memory opening fill structures 58 vertically extend through the alternating stack (32, 46). Each of the memory opening fill structures 58 comprises a respective vertical stack of memory elements (which may comprise portions of a memory material layer 54 located at levels of the electrically conductive layers 46), a respective vertical semiconductor channel 60, and a respective drain region 63. At least one uppermost electrically conductive layer 46 may comprise a drain side select gate electrode. At least one bottommost electrically conductive layer 46 may comprise a source side select gate electrode. The remaining electrically conductive layers 46 may comprise word lines. Each word line functions as a common control gate electrode for the plurality of vertical NAND strings (e.g., memory opening fill structures 58).

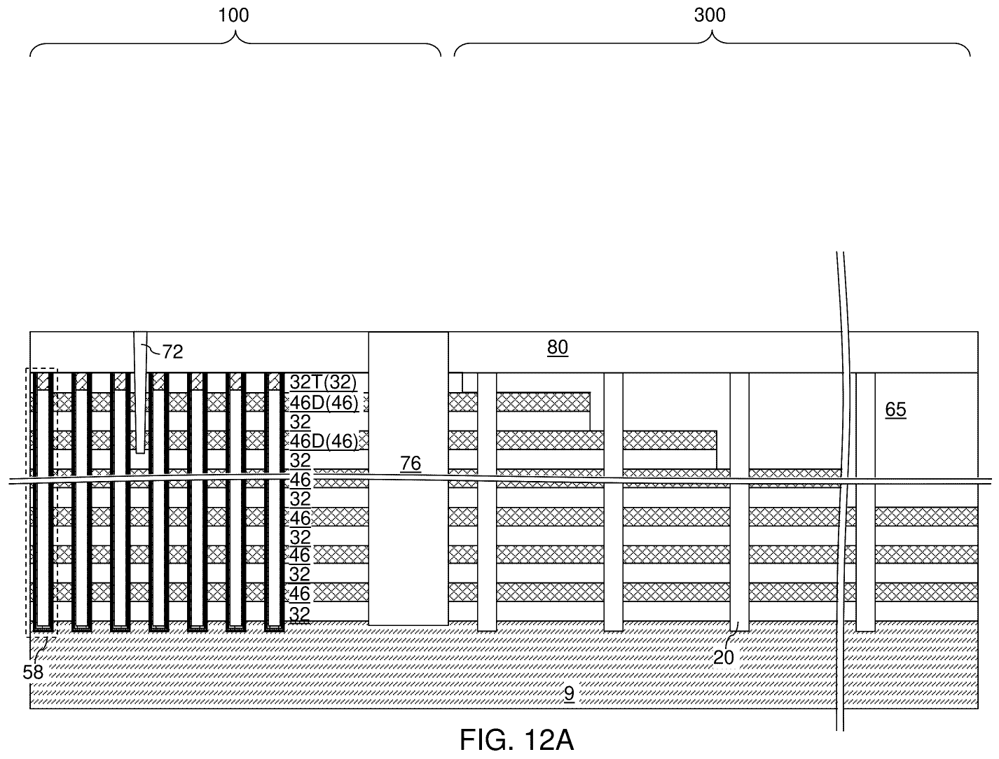

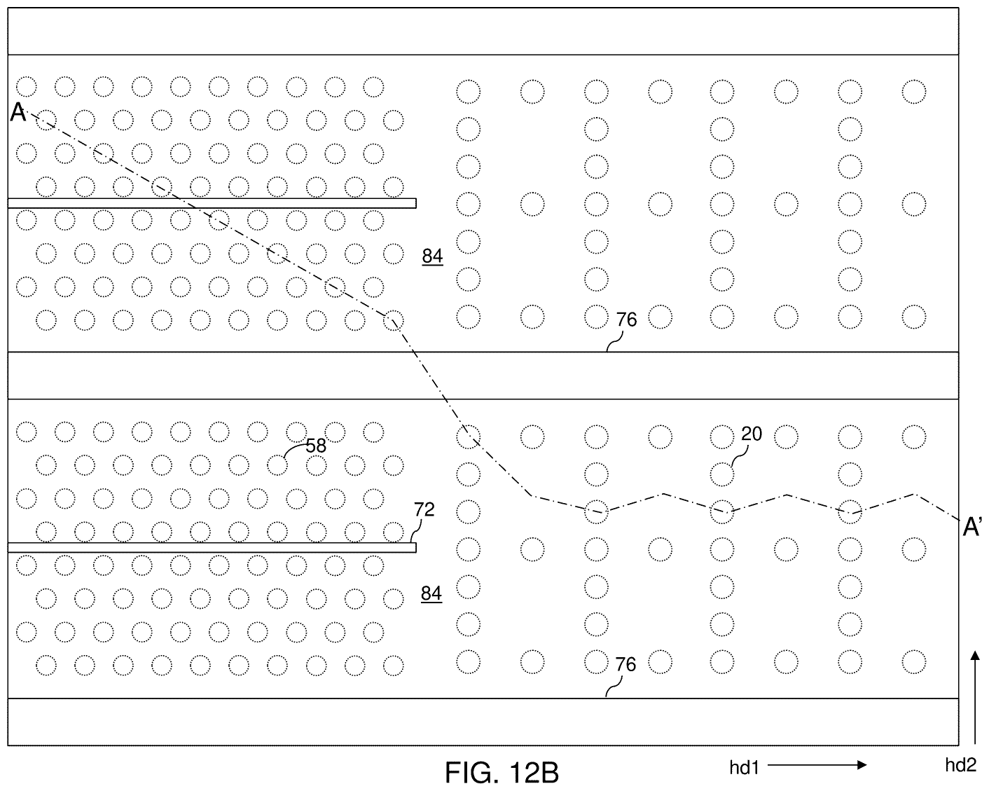

Referring to FIGS. 12A and 12B, a dielectric fill material, such as silicon oxide can be deposited in the lateral isolation trenches 79. Excess portions of the dielectric fill material can be removed from above the contact-level dielectric layer 80. Each remaining portion of the dielectric fill material that fills a respective one of the lateral isolation trenches 79 constitutes a lateral isolation trench fill structure 76, which may be a dielectric wall structure. In an alternative embodiment, an insulating spacer having a tubular configuration can be formed in peripheral portions of each of the lateral isolation trenches 79, and a through-stack conductive via structure may be formed within a respective one of the insulating spacers. In this case, each lateral isolation trench fill structure 76 may comprise a combination of a through-stack conductive via structure and an insulating spacer that laterally surrounds the through-stack conductive via structure.

An alternating stack (32, 46) of insulating layers 32 and electrically conductive layers 46 can be formed in a memory block area between each neighboring pair of lateral isolation trench fill structures 76. The alternating stack (32, 46) can include at least one drain-select-level electrically conductive layer 46D (i.e., at least one drain side select gate electrode) which is employed to activate or deactivate NAND strings (e.g., the memory opening fill structures 58 and adjacent portions of the electrically conductive layers 46) vertically extending through the alternating stack (32, 46). A subset of the electrically conductive layers 46 that underlies the drain-select-level electrically conductive layers 46D comprises word lines, which comprise control electrodes of the NAND strings. A subset of one or more bottommost electrically conductive layers 46 which underlies the word lines comprises source side select gate electrodes.

Drain-select-level isolation trenches can be formed through the drain-select-level electrically conductive layers 46D, for example, by forming a patterned photoresist layer including elongated openings that laterally extend along the first horizontal direction hd1 over the contact-level dielectric layer 80, and by performing an anisotropic etch process. Each of the drain-select-level electrically conductive layers 46D may be divided into a respective plurality of drain-select-level electrically conductive strips (i.e., drain side select gate electrodes). The patterned photoresist layer can be removed, for example, by ashing. A dielectric fill material, such as silicon oxide, can be deposited in the drain-select-level isolation trenches to form drain-select-level isolation structures 72. Optionally, excess portions of the dielectric fill material may be removed from above the horizontal plane including the top surface of the contact-level dielectric layer 80.

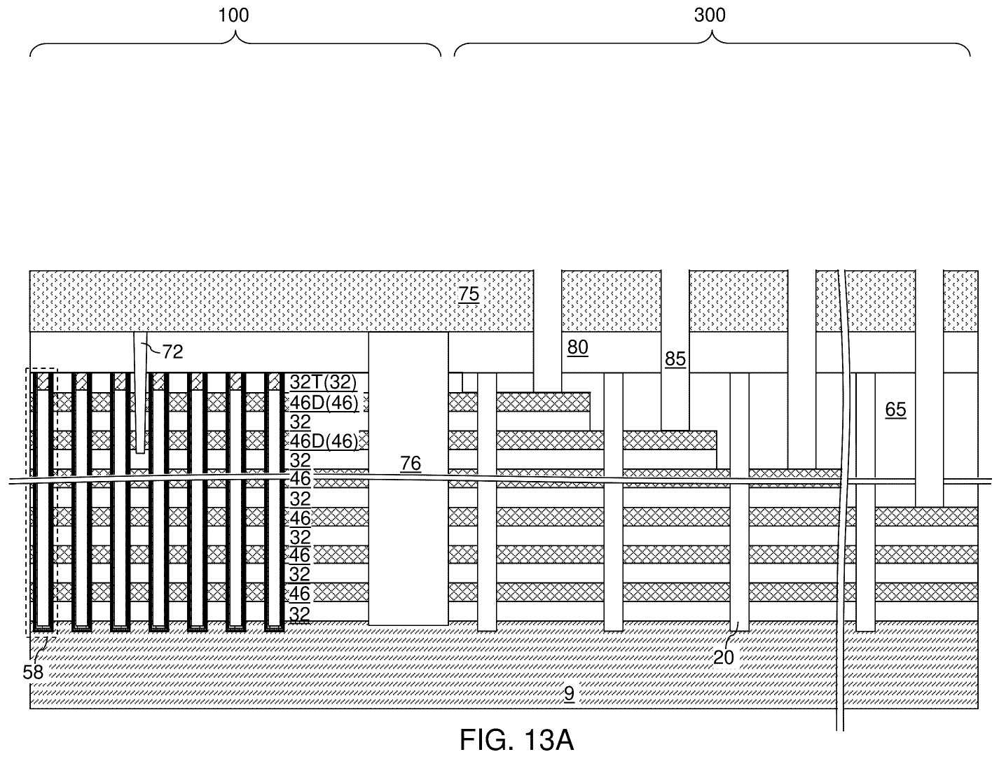

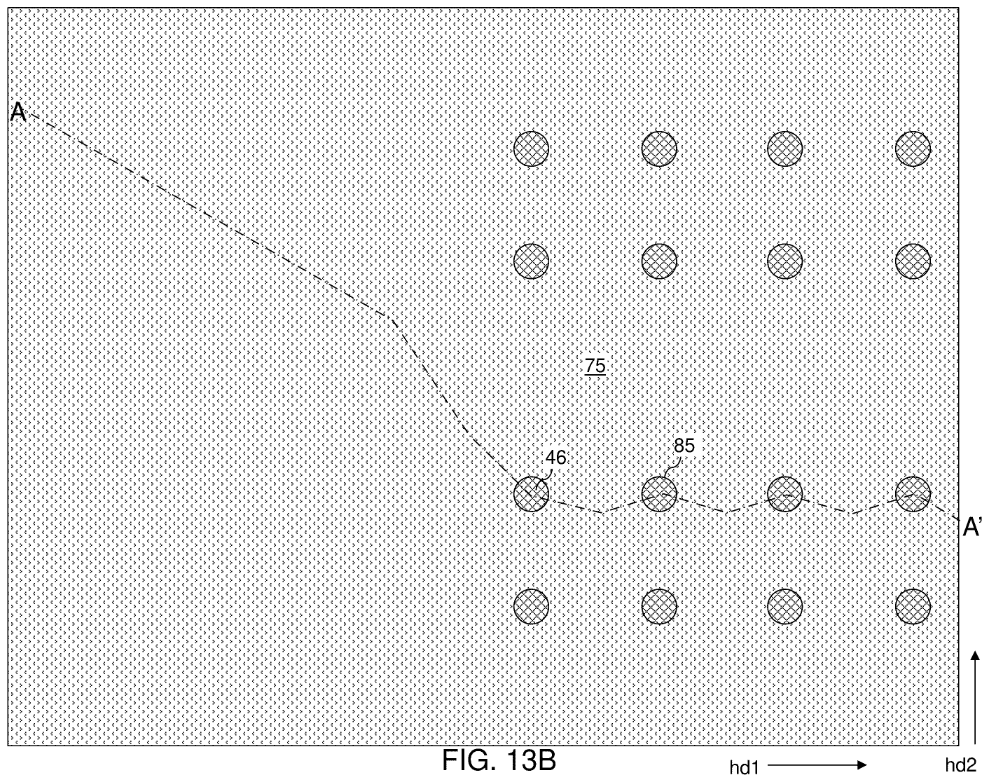

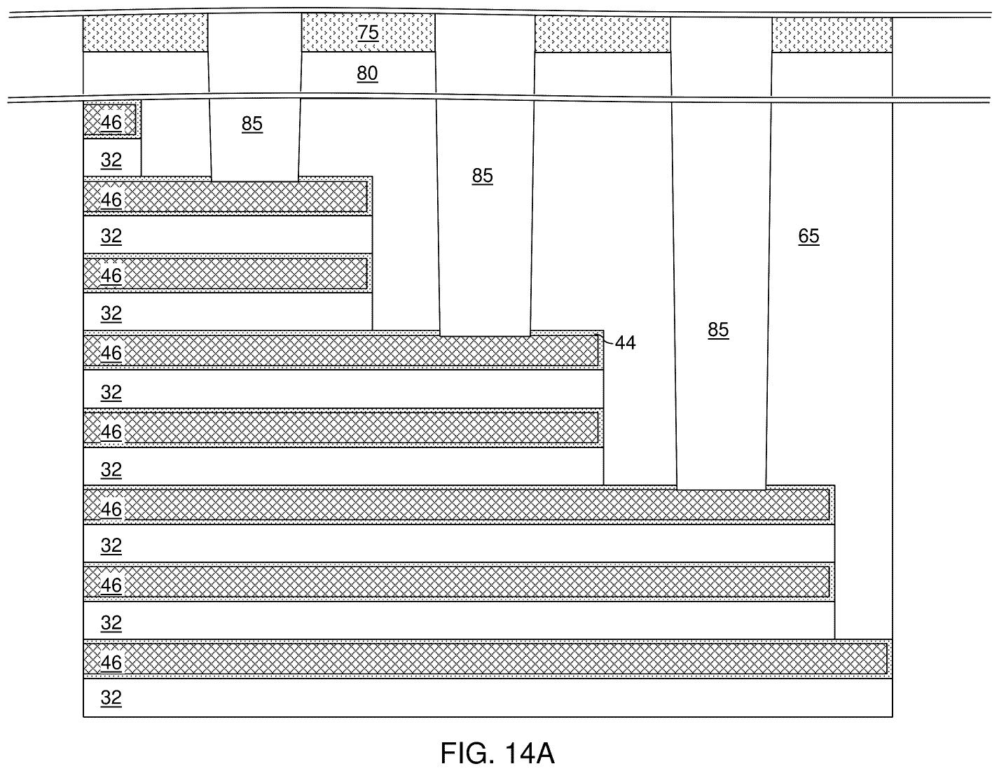

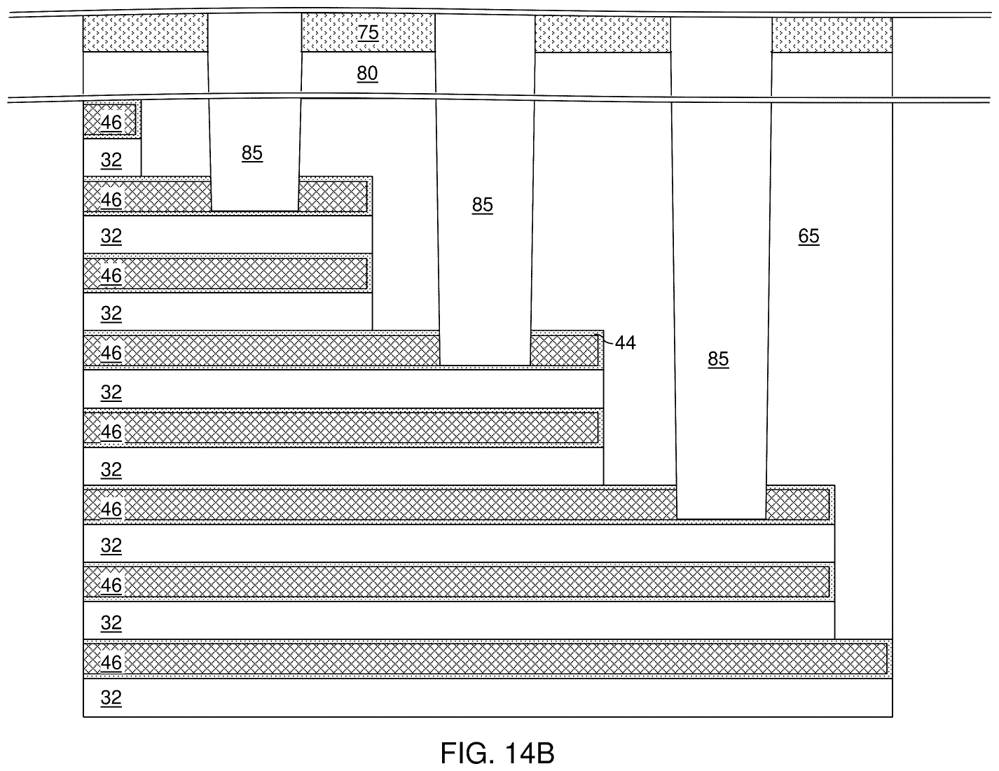

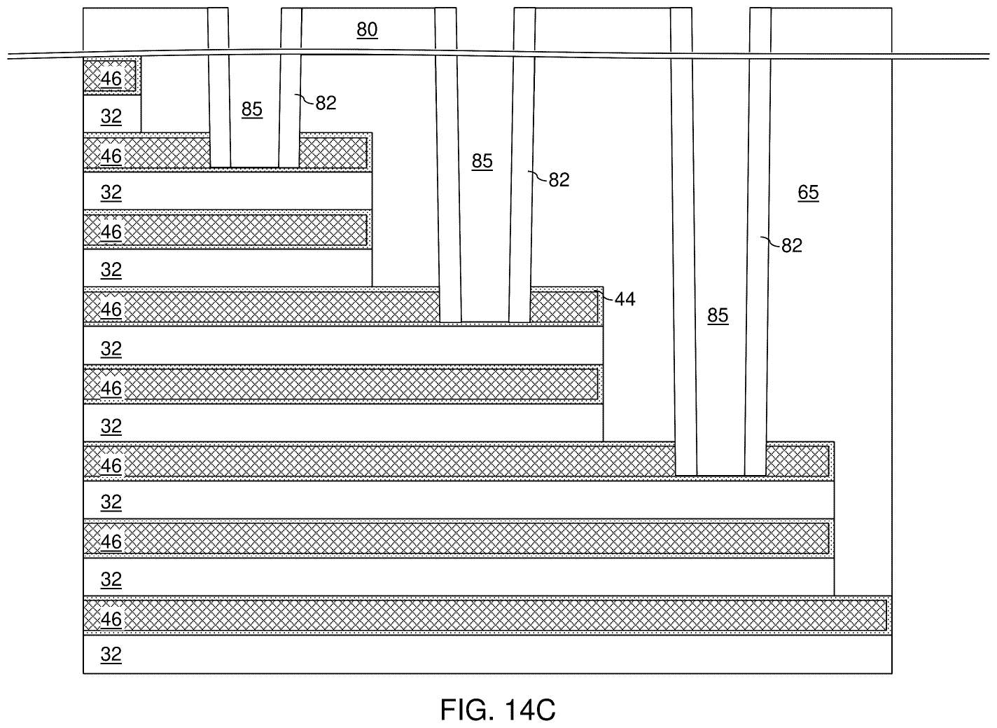

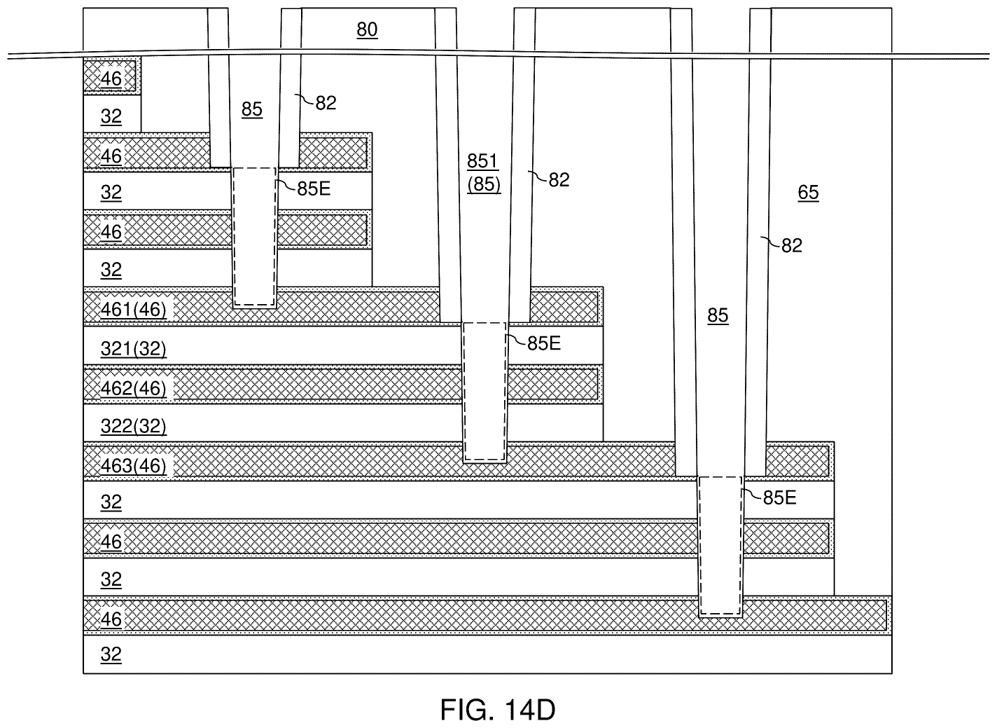

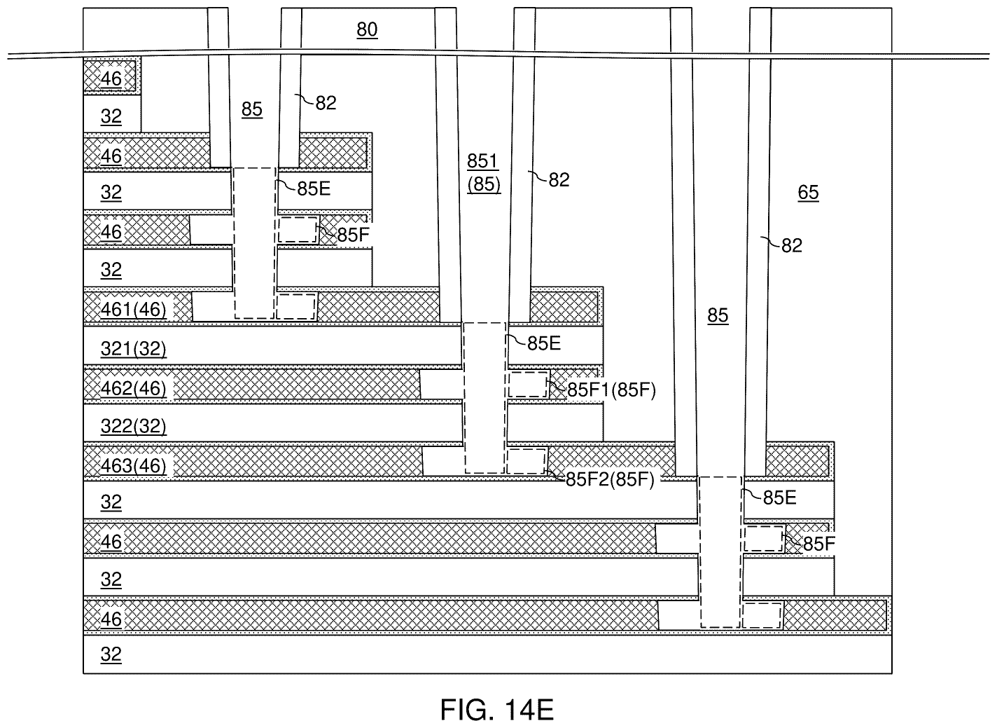

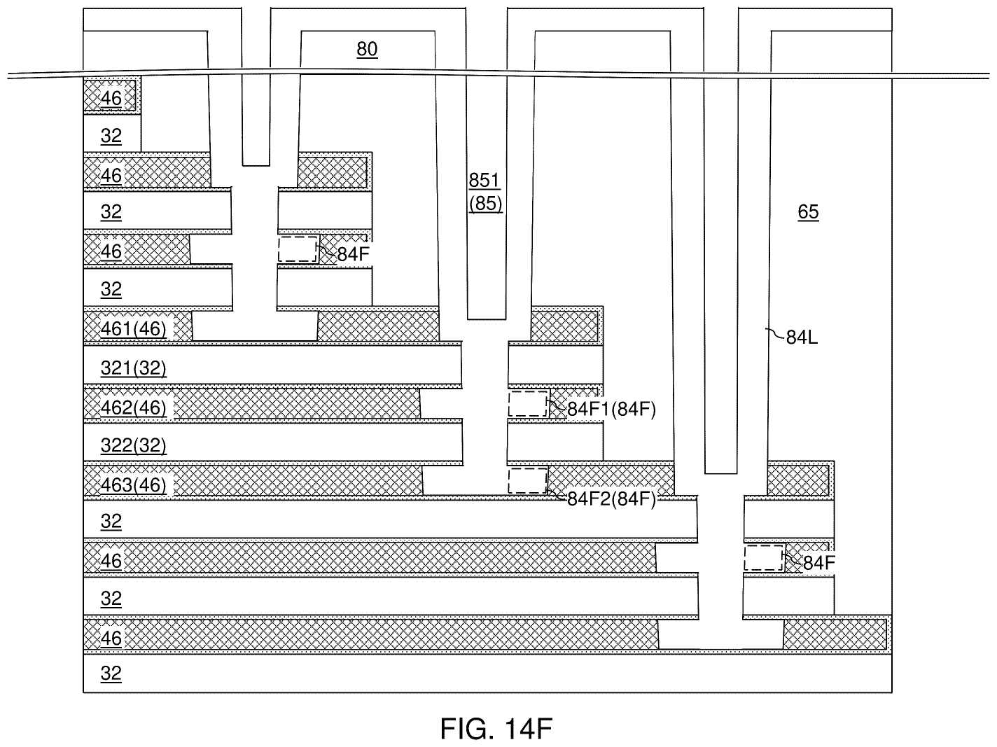

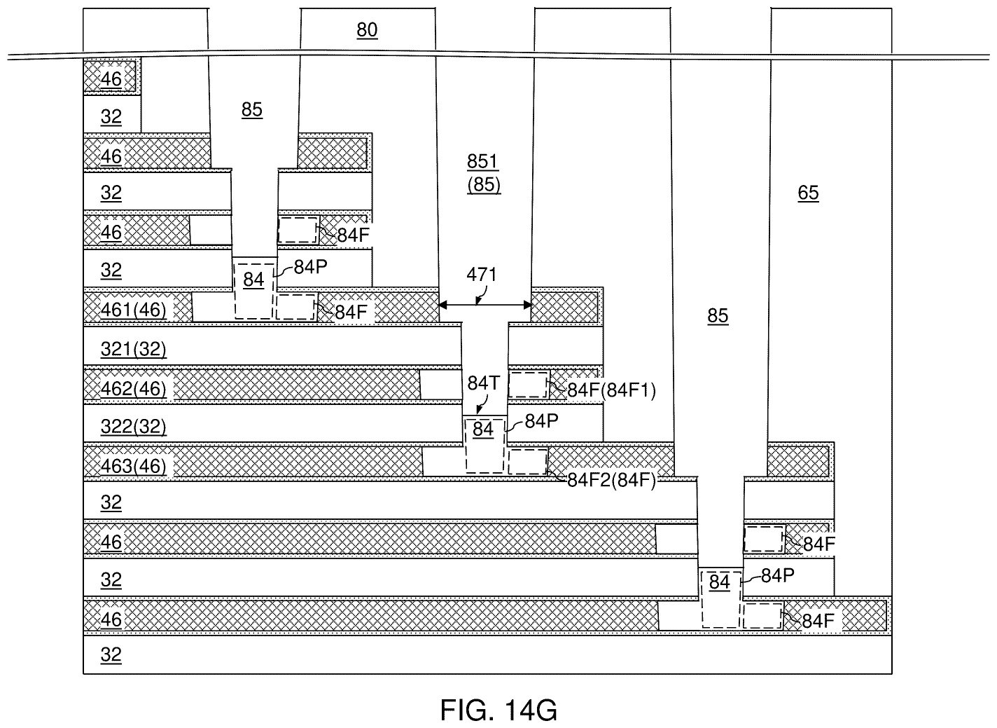

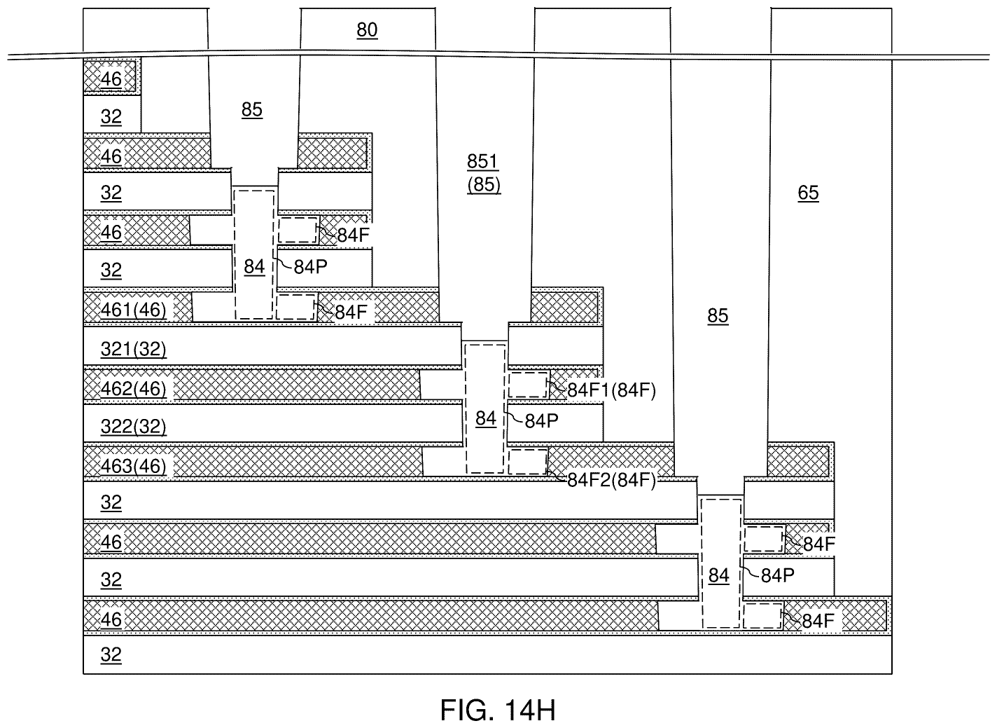

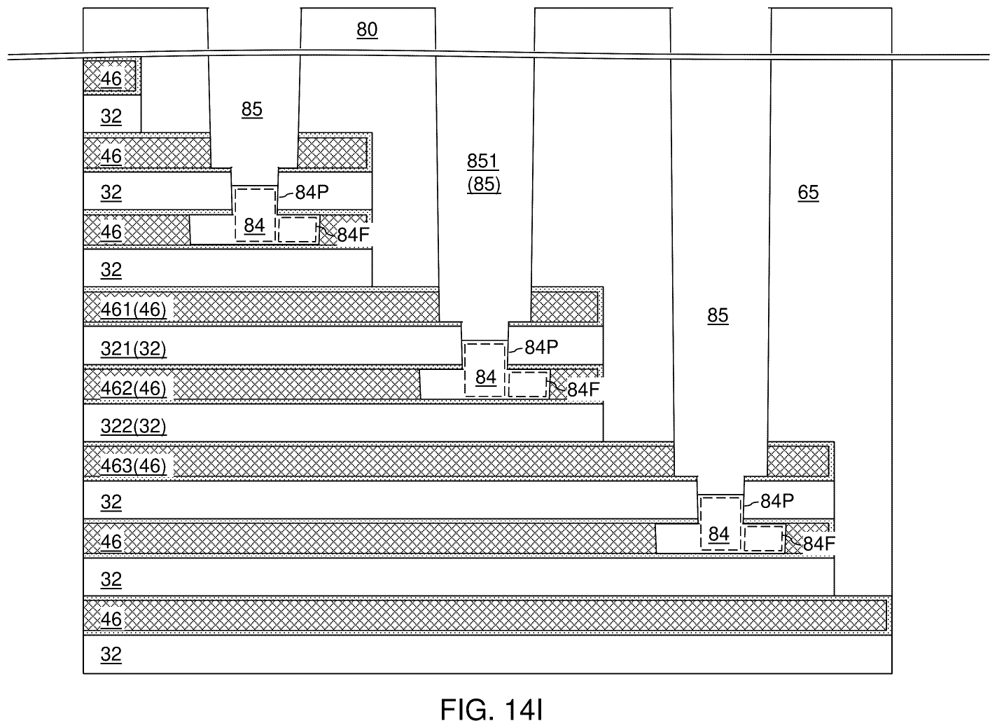

Referring to FIGS. 13A, 13B, and 14A, a first photoresist layer 75 can be applied over the contact-level dielectric layer 80, and can be lithographically patterned to form openings in areas in the contact region 300 that overlies a respective horizontally-extending surface segment of the electrically conductive layers 46. A first step of an anisotropic etch process can be performed to transfer the pattern of the openings in the first photoresist layer 75 through the contact-level dielectric layer 80, the contact-level dielectric layer 80, and the retro-stepped dielectric material portion 65. Layer contact via cavities 85 can be formed through the contact-level dielectric layer 80, the contact-level dielectric layer 80, the retro-stepped dielectric material portion 65, and each outer blocking dielectric layer 44 (if present) in contact with a stepped bottom surface of the retro-stepped dielectric material portion 65 over a top surface of a respective one of the electrically conductive layers 46. Each electrically conductive layer 46 may have a top surface segment that is exposed to a respective overlying layer contact via cavity 85. The width of the bottoms of the layer contact via cavities 85 can be between 100 nm and 200 nm, such as between 125 nm and 175 nm, although lesser and greater widths may also be employed.

Referring to FIG. 14B, a second step of the anisotropic etch process can be performed to etch unmasked portions of the electrically conductive layers 46 underneath the layer contact via cavities 85. The etch chemistry of the second step of the anisotropic etch process can be selected to etch the metallic material(s) of the electrically conductive layers 46 selective to the dielectric material of the outer blocking dielectric layer 44 and/or selective to the material of the insulating layers 32. Each layer contact via cavity 85 can be vertically extended through the thickness of a respective immediately underlying electrically conductive layer 46. A top surface of a horizontally-extending portion of an outer blocking dielectric layer 44 (if present) or a top surface of an underlying insulating layer 32 may be physically exposed underneath each layer contact via cavity 85 after the second etch process of the anisotropic etch process. The first photoresist layer 75 can be subsequently removed, for example, by ashing.

In summary, a set of layer contact via cavities 85 can be formed such that each layer contact via cavity 85 extends through the retro-stepped dielectric material portion 65 through a respective first electrically conductive layer 46 of the electrically conductive layers 46. In other words, for each layer contact via cavity 85, there exists a first electrically conductive layer 46 through which the layer contact via cavity 85 vertically extends. A cylindrical sidewall surface of a first electrically conductive layer 46 is exposed to the respective layer contact via cavity 85 upon formation of a layer contact via structure 86 through the first electrically conductive layer 46.

Referring to FIG. 14C, a sacrificial tubular spacer 82 can be formed in a peripheral volume of each layer contact via cavity 85 by conformally depositing a sacrificial spacer material layer on the physically exposed surfaces of the layer contact via cavities 85 and over the contact-level dielectric layer 80, and by performing an anisotropic sidewall spacer etch process that etches horizontally-extending portions of the sacrificial spacer material layer. In one embodiment, each sacrificial tubular spacer 82 may comprise doped or undoped silicon oxide, silicon oxynitride, silicon nitride, silicon carbonitride, amorphous carbon, amorphous silicon, or polymer. The thickness of each sacrificial tubular spacer 82, as measured between an inner sidewall and an outer sidewall, may be in a range from 25 nm to 75 nm, such as from 40 nm to 60 nm, although lesser and greater thicknesses may also be employed.

Referring to FIG. 14D, an anisotropic etch process can be performed to etch portions of the alternating stack (32, 46) that are not masked by the contact-level dielectric layer 80 and the sacrificial tubular spacers 82. The anisotropic etch process may etch at least one electrically conductive layer 46 underlying the bottom surfaces of the sacrificial tubular spacers 82. For example, the anisotropic etch process may etch two electrically conductive layers 46 and two insulating layers 32 underlying the bottom surfaces of the sacrificial tubular spacers 82.

For layer contact via cavities vertically extending through a bottommost electrically conductive layer 46 or through a second-from-bottom electrically conductive layer 46, dielectric isolation structures (not shown) such as shallow trench isolation structures may be provided to prevent formation of layer contact via structures on the carrier substrate 9. Generally, the anisotropic etch process vertically extends each of the layer contact via cavities 85. For example, a first layer contact via cavity 851 that vertically extends through a respective first electrically conductive layer 461 prior to the anisotropic etch process at the processing step of FIG. 14D, a vertically-extended portion 85E of the layer contact via cavity 851 extends at least through a first insulating layer 321 of the insulating layers 32 and into a second electrically conductive layer 462 of the electrically conductive layers 46, and may optionally extend into a second insulating layer 322 of the insulating layers 32 and may optionally extend into a third electrically conductive layer 463 of the electrically conductive layers 46.

Referring to FIG. 14E, a first isotropic etch process can be performed to isotropically etch the material of the electrically conductive layers 46 selective to a material of the insulating layers 32 and preferably selective to a material of the sacrificial tubular spacer 82. For example, if the electrically conductive layers 46 comprise tungsten, the first isotropic etch process may comprise a wet etch process employing a mixture of phosphoric acid and hydrogen peroxide, or an amine based organic etchant. Fin cavities 85F are formed in the volumes from which the material of the electrically conductive layers 46 is removed. In case a pair of electrically conductive layers 46 are physically exposed around a vertically-extended portion 85E of a layer contact via cavity 851, a first fin cavity 85F1 and a second fin cavity 85F2 which underlies the first fin cavity 85F1 may be formed around the vertically-extended portion 85E of the layer contact via cavity 851.

For each first contact via cavity 851 that vertically extends through, from top to bottom, a first electrically conductive layer 461, a second electrically conductive layer 462, and a third electrically conductive layer 463, a first fin cavity 85F1 having an annular shape can be formed in a volume from which an annular portion of the second electrically conductive layer 462 is removed, and a second fin cavity 85F2 having an annular shape can be formed in a volume from which an annular portion of the third electrically conductive layer 463 is removed. The lateral etch distance of the first isotropic etch process can be the same as the lateral distance between an inner periphery of an annular top surface of a fin cavity 85F and an outer periphery of the annular top surface of the fin cavity 85F. Further, if a fin cavity 85F has an annular bottom surface, the lateral etch distance of the first isotropic etch process can be the same as the lateral distance between an inner periphery of an annular bottom surface of a fin cavity 85F and an outer periphery of the annular bottom surface of the fin cavity 85F. The lateral etch distance may be greater than the lateral thickness of each sacrificial tubular spacer 82 (as measured between an inner sidewall and an outer sidewall). In one embodiment, a cylindrical sidewall of each fin cavity 85 may be laterally offset outward relative to the top periphery of an outer sidewall of an overlying sacrificial tubular spacer 82 in a plan view (such as a top-down view). The lateral etch distance of the first isotropic etch process may be in a range from 20 nm to 150 nm, such as from 40 nm to 10 nm, although lesser and greater lateral etch distances may also be employed. The height of the fin cavity 85F may be the same as a thickness of the electrically conductive layer 46 plus two times a thickness of the outer blocking dielectric layer 44 (if present). Furthermore, the thickness of the fin cavity 85F may be less than the width (e.g., diameter) of the contact via cavity 85 at the level of an overlying insulating layer 32. For example, the thickness of the fin cavity 85F may range from 15 nm to 40 nm, such as 20 nm to 30 nm, while the width (e.g., diameter) of the contact via cavity 85 at the level of an overlying insulating layer 32 may range from 30 nm to 70 nm, such as 40 nm to 60 nm.

Referring to FIG. 14F, a dielectric material layer 84L can be deposited on physically exposed surfaces of the layer contact via cavity 85 and the sacrificial tubular spacers 82. The dielectric material layer 84L comprises a dielectric material, such as undoped silicate glass, a doped silicate glass, organosilicate glass, silicon oxide, silicon oxynitride, etc. The dielectric material layer 84L may comprise the same material as the sacrificial tubular spacers 82. In this case, the sacrificial tubular spacers 82 may be merged into the dielectric material layer 84L. The dielectric material layer 84L may be deposited by a conformal deposition process, such as a chemical vapor deposition process.

The thickness of the dielectric material layer 84L is selected such that it does not completely fill the upper portions of the layer contact via cavities 85 at the levels of the sacrificial tubular spacers 82, but completely fills the fin cavities 85F which have a height that is narrower than the width of the layer contact via cavities 85. This thickness of the dielectric material layer 84L may be 15 nm to 40 nm, such as 20 nm to 30 nm. The dielectric material layer 84L can be conformally deposited to fill the portions of the layer contact via cavities 85 that underlie horizontally-extending surface segments of the stepped bottom surface of the retro-stepped dielectric material portion 65.

The duration of the conformal deposition process that deposits the dielectric material layer 84L can be selected such that all volumes of the layer contact via cavities 85 underlying the horizontally-extending surface segments of the stepped bottom surface of the retro-stepped dielectric material portion 65 (e.g., below the bottom of the sacrificial tubular spacers 82) are completely filled, while a center region of each layer contact via cavity 85 that overlies the stepped bottom surface of the retro-stepped dielectric material portion 65 (e.g., above the bottom of the sacrificial tubular spacers 82) is not completely filled with the dielectric material layer 84L. Each portion of the dielectric material layer 84L that fills a respective fin cavity 85F constitutes a dielectric fin 84F. In case the layer contact via cavity 85 comprises a first fin cavity 85F1 and a second fin cavity 85F2 after the processing steps of FIG. 14E, the first fin cavity 85F1 may be filled with a first dielectric fin 84F1 and the second fin cavity 85F2 may be filled with a second dielectric fin 84F2.

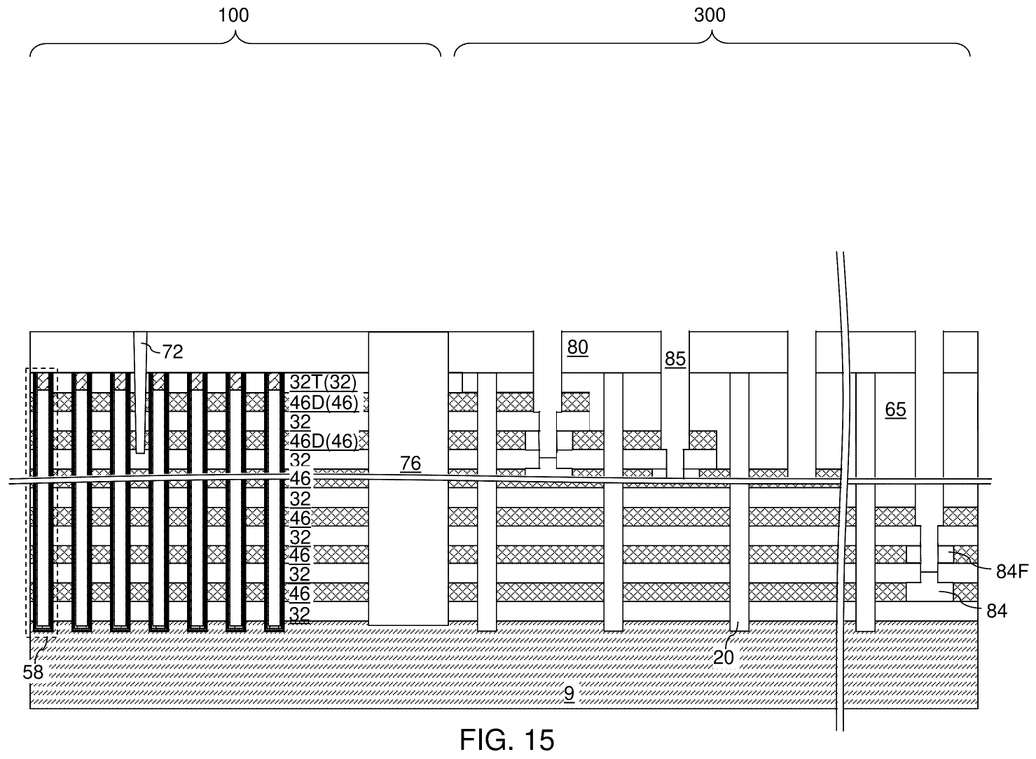

Referring to FIG. 14G and 15, a second isotropic etch process is performed to isotropically recess physically exposed portions of the dielectric material layer 84L. The second isotropic etch process may comprise a timed wet etch process. If the sacrificial tubular spacers 82 and the dielectric material layer 84L comprise silicon oxide, then the wet etch may comprise a dilute hydrofluoric acid wet etch. The duration of the second isotropic etch process can be selected such that all portions of the dielectric material layer 84L that are formed at the levels of the sacrificial tubular spacers 82 in the layer contact via cavities 85 are removed by the second isotropic etch process. A cylindrical sidewall of an opening in a respective electrically conductive layer 46 is physically exposed around each layer contact via cavity 85 after the processing steps of FIGS. 14G and 15.

In the embodiment of FIG. 14G, cylindrical sidewalls of the first dielectric fins 84F1 are exposed in the first layer contact via cavity 851. In a first alternative embodiment illustrated in FIG. 14H, the duration of the second isotropic etch process is reduced, such that cylindrical sidewalls of the first and second dielectric fins (84F1, 84F2) are not exposed in the first layer contact via cavity 851.

Each remaining portion of the dielectric material layer 84L after the second isotropic etch process comprises a dielectric base 84. Each dielectric base 84 is fills a volume of at least one fin cavity 85F (e.g., 85F2) and at least a part of the vertically-extended portion 85E of the layer contact via cavity 85 as provided after the processing steps of FIG. 14E. In one embodiment, each dielectric base 84 comprises a dielectric pillar portion 84P from which at least one dielectric fin 84F (e.g., 84F2) and an optional addition dielectric fin 84F (e.g., 84F1 in FIG. 14H) laterally protrude.

In one embodiment shown in FIG. 14G, the top surface of the dielectric pillar portion 84P filling the bottom part of the first layer contact via cavity 851 may be formed below a horizontal plane including a top surface of a second insulating layer 322 that underlies the second electrically conductive layer 461 and above a horizontal plane including a bottom surface of the second insulating layer 322. In this embodiment, the first dielectric fin 84F1 is vertically separated from the respective dielectric pillar portion 84P located in the same layer contact via cavity 85.

In another embodiment shown in FIG. 14H, the top surface of the dielectric pillar portion 84P may be formed below a horizontal plane including a top surface of a first insulating layer 321 that underlies the first electrically conductive layer 461 and above a horizontal plane including a bottom surface of the first insulating layer 321. In this embodiment, the first dielectric fin 84F1 is physically connected to and laterally protrudes from the respective dielectric pillar portion 84P located in the same layer contact via cavity 85.

Generally, each remaining portion of the dielectric material layer 84L that underlies a respective layer contact via cavity 85 constitutes a dielectric base 84. Each dielectric base 84 is self-aligned to the geometrical center of a respective overlying layer contact via cavity 85 in a plan view (such as a top-down view). In one embodiment, each dielectric base 84 comprises at least one dielectric fin 84F (e.g., 84F2), and may optionally comprise a second, overlying dielectric fin 84F (e.g., 84F1, as shown in FIG. 14H). Each dielectric fin 84F may have a greater area in a plan view (such as a top-down view) than the area enclosed by the bottom periphery of the cylindrical surface of the opening in an overlying electrically conductive layer 46 (which is referred to as a first electrically conductive layer 461 for the dielectric base 84 including at least one dielectric fin 84F).

A cylindrical sidewall surface of an opening through the first electrically conductive layer 461 is exposed to the first layer contact via cavity 851. The second and third electrically conductive layers (462, 463) underlie the first electrically conductive layer 461. For each first layer contact via cavity 851 that vertically extends through an opening in a first electrically conductive layer 461, the dielectric base 84 comprising a dielectric material and contacting at least one electrically conductive layer 46 (e.g., the third electrically conductive layer 463 in FIGS. 14G and 14H, and the second electrically conductive layer 462 in FIG. 141) is provided. As shown in FIG. 14H, the dielectric base 84 may also optionally contact the second electrically conductive layer 462 located between the first and the third electrically conductive layers (461, 463) in addition to contacting the third electrically conductive layer 463. The dielectric base 84 comprises a cylindrical surface segment that contacts a cylindrical sidewall surface segment of the cylindrical opening through the second insulating layer 322, as shown in FIGS. 14G and 14H, and optionally contacts a cylindrical sidewall surface segment of the cylindrical opening through the first insulating layer 321 (as shown in FIG. 14H).

The topmost surface 84T of the dielectric base 84 has a lesser area than an area enclosed by a bottom periphery of the cylindrical sidewall surface of the opening 471 in the first electrically conductive layer 461, as shown in FIG. 14G. In one embodiment, the dielectric base 84 comprises a second dielectric fin 84F2 having a greater area in a plan view than the area enclosed by the bottom periphery of the cylindrical sidewall surface of the opening 471 in the first electrically conductive layer 461. The dielectric base 84 further comprises a dielectric pillar portion 84P from which the second dielectric fin 84F2 laterally protrudes, and a top surface 84T of the dielectric pillar portion 84P is exposed to the layer contact via cavity 85.

The second dielectric fin 84F2 laterally protrudes from the dielectric pillar portion 84P and has a lesser vertical extent than the dielectric pillar portion 84P. The second dielectric fin 84F2 is located within an opening through the third electrically conductive layer 463 that underlies the first electrically conductive layer 461. In one embodiment, each dielectric base 84 may further comprise an additional (e.g., first) dielectric fin 84F1 that laterally protrudes from the dielectric pillar portion 84P and overlies the second dielectric fin 84F2. The first dielectric fin 84F1 is located within an opening through a second electrically conductive layer 462 that overlies the third electrically conductive layer 463. In one embodiment, the first dielectric fin 84F1 comprises a cylindrical sidewall that contacts a cylindrical sidewall of an opening through the second electrically conductive layer 462.

In one embodiment, the dielectric pillar portion 84P comprises a first cylindrical sidewall surface that contacts a cylindrical sidewall surface segment of an opening through a second insulating layer 322 of the insulating layers 32 that is located between the third electrically conductive layer 463 and the second electrically conductive layer 462, as shown in FIG. 14G. Optionally the dielectric pillar portion 84P comprises a second cylindrical sidewall surface that contact a cylindrical sidewall surface of an opening through a first insulating layer 321 of the insulating layers 32 that is located below the first electrically conductive layer 461, as shown in FIG. 14H. In one embodiment, a bottommost surface of the dielectric base 84 is located within a horizontal plane including a bottom surface of the third electrically conductive layer 463, as shown in FIGS. 14G and 14H.

Referring to FIG. 14I, a second alternative configuration of the exemplary structure is illustrated, which can be derived from the exemplary structure illustrated in FIGS. 14G, 14H and 15 by reducing the depth of the vertically-extended portions 85E of the layer contact via cavities 85 at the processing steps of FIG. 14D. Specifically, for each layer contact via cavity 85 that vertically extends through a respective first electrically conductive layer 461, the vertically-extended portion 85E of the layer contact via cavity 85 extends through a respective first insulating layer 321 and into a respective second electrically conductive layer 462, may optionally extend into a second insulating layer 322, and does not extend into a respective third electrically conductive layer 463. In this case, each layer contact via cavity 85 comprises a single fin cavity 85F after the processing steps that correspond to the processing steps of FIG. 14E. Thus, each dielectric base 84 comprises a dielectric pillar portion 84P and a single dielectric fin 84F. Each dielectric base 84 is self-aligned to the geometrical center of a respective overlying layer contact via cavity 85 in a plan view (such as a top-down view).

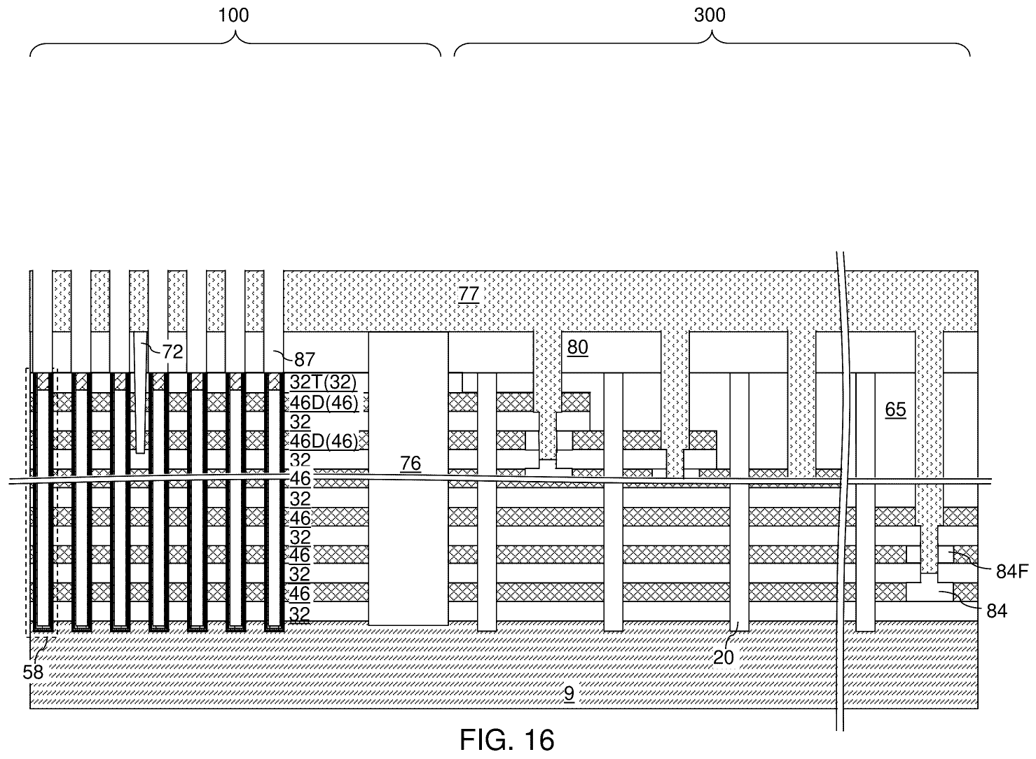

Referring to FIG. 16, a second photoresist layer 77 can be applied over the contact-level dielectric layer 80, and can be lithographically patterned to form openings having the same pattern as the pattern of the memory opening fill structures 58. An anisotropic etch process can be performed to transfer the pattern of the openings in the second photoresist layer 77 through the contact-level dielectric layer 80. Drain contact via cavities 87 are formed through the contact-level dielectric layer 80. A top surface of a drain region 63 can be physically exposed underneath each drain contact via cavity 87.

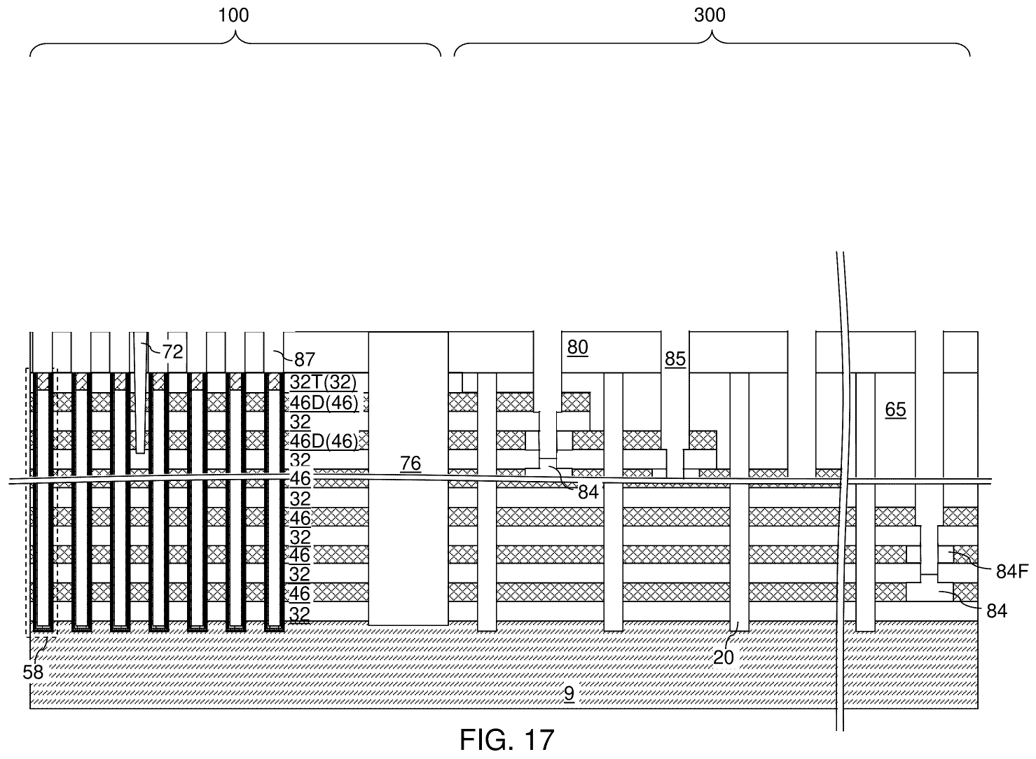

Referring to FIG. 17, the second photoresist layer 77 can be removed, for example, by ashing.

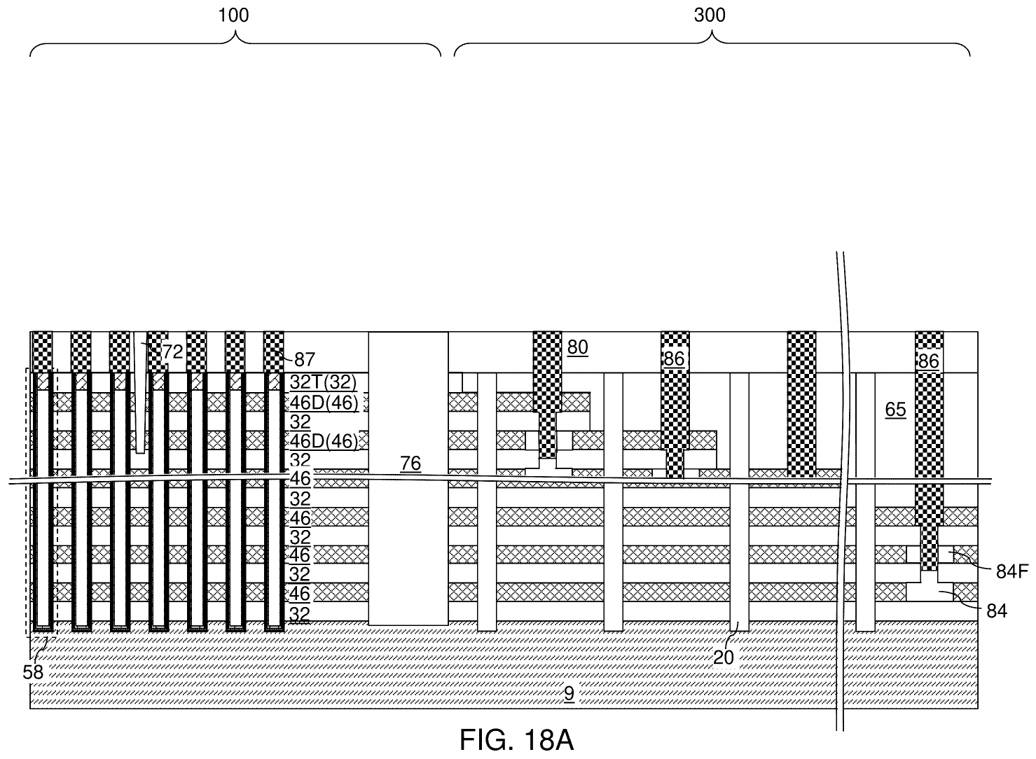

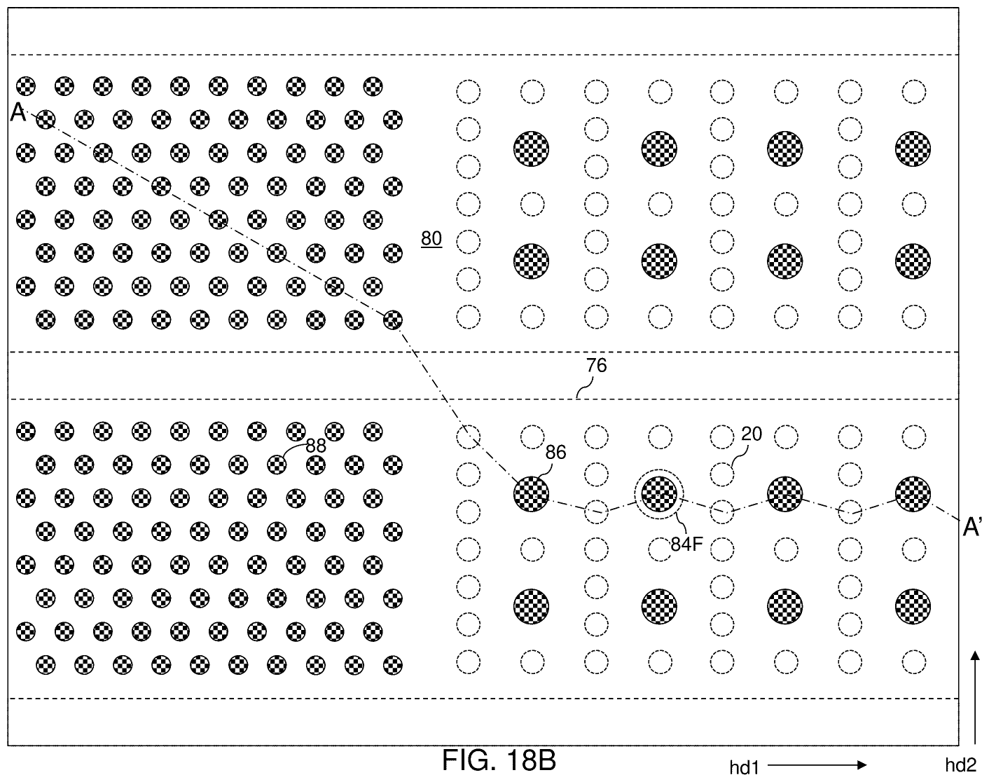

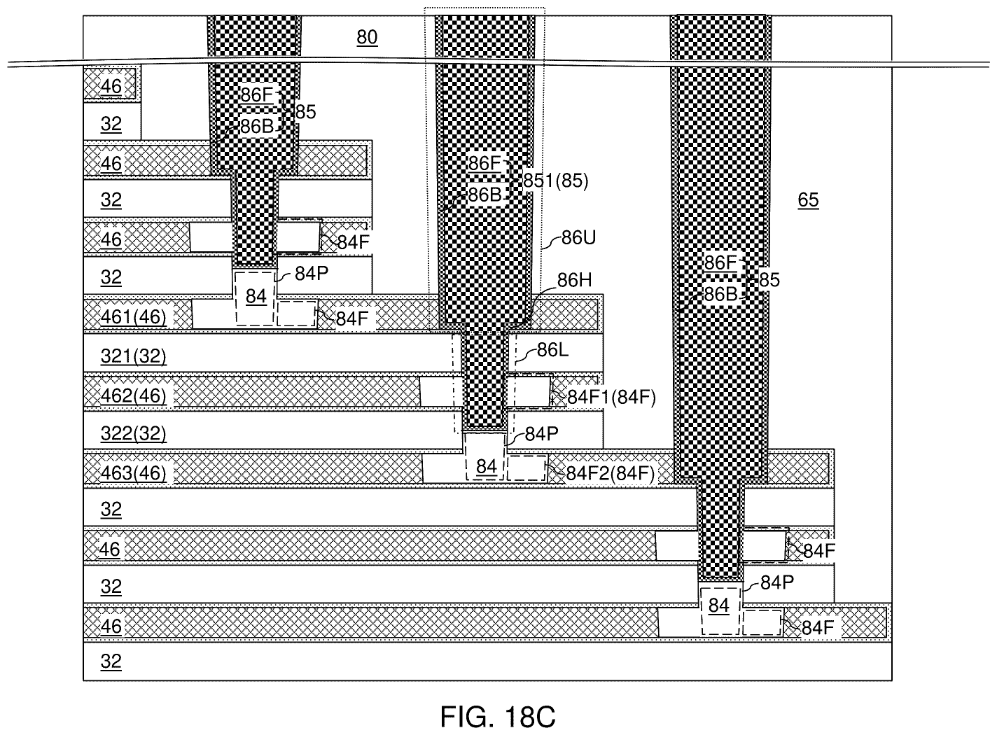

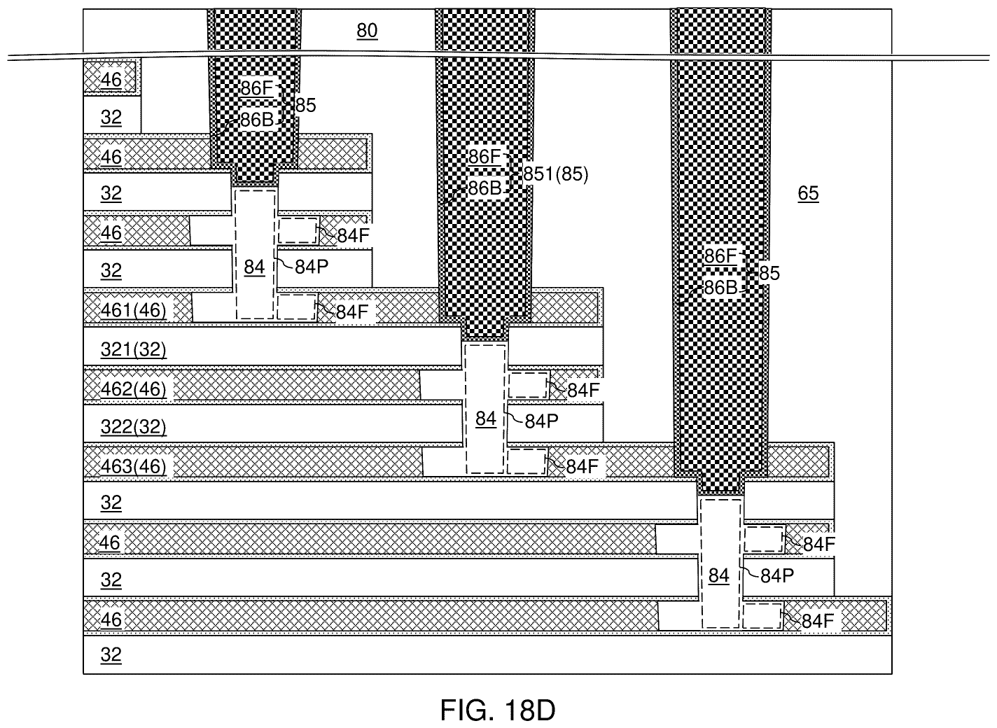

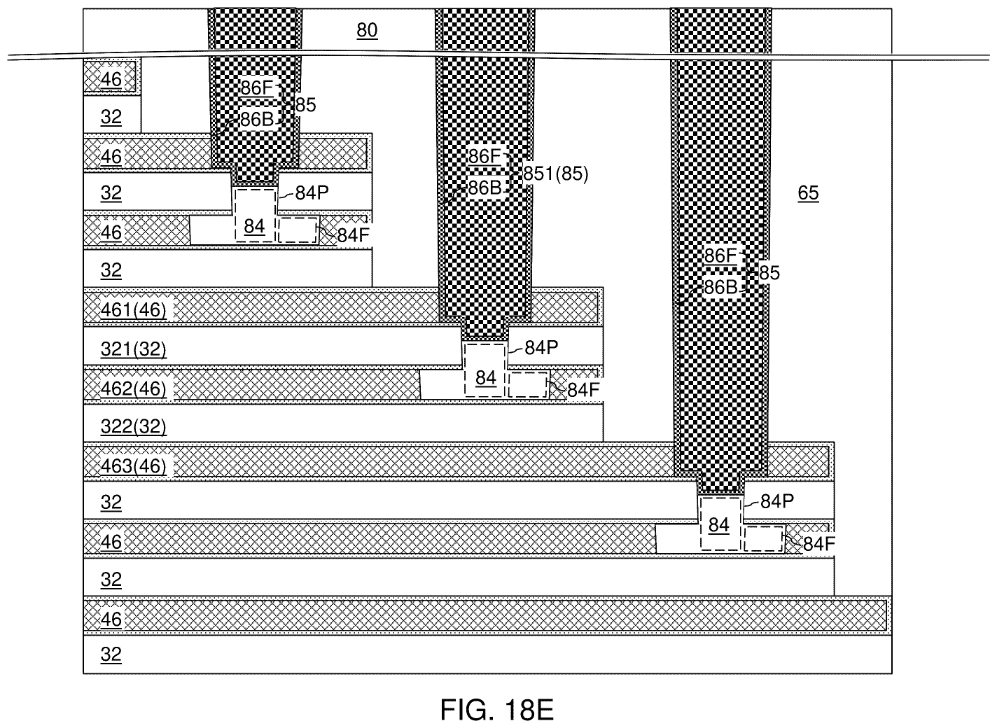

Referring to FIGS. 18A-18C, at least one conductive material, such as at least one metallic material, can be deposited in the layer contact via cavities 85 and above the contact-level dielectric layer 80. The at least one conductive material may comprise a metallic barrier material (such as TiN, TaN, WN, and/or MoN) and a metallic fill material (such as W, Cu, Mo, Ru, Co, Ti, Ta, etc.). Excess portions of the at least one conductive material can be removed from above the horizontal plane including the top surface of the contact-level dielectric layer 80 by performing a planarization process. The planarization process may comprise a chemical mechanical polishing process and/or a recess etch process. Each remaining portion of the at least one conductive material that fills a respective layer contact via cavity 85 constitutes a layer contact via structure 86. In one embodiment, each layer contact via structure 86 may comprise metallic barrier line 86B comprising a metallic barrier material and a metallic fill material portion 86F comprising a metallic fill material. Drain contact via structures 88 are formed in the drain contact via cavities 87 concurrently with formation of the layer contact via structures 86 in the layer contact via cavities 85.

In one embodiment, top surface of the layer contact via structures 86 may be formed within the horizontal plane including the top surface of the contact-level dielectric layer 80. Each layer contact via structure 86 may comprise a cylindrical upper portion 86U that vertically extends through the retro-stepped dielectric material portion 65 and the opening 471 in the respective first electrically conductive layer 461, and a cylindrical lower portion 86L that protrudes downward from the annular bottom surface of the cylindrical portion into an opening in a first insulating layer 321 that underlies the first electrically conductive layer 461. The lower portion 86L has a smaller width (e.g., diameter) than the upper portion 86U of the same layer contact via structure 86, such that a horizontal step 86H is located between the upper and lower portions (86U, 86L) of the layer contact via structure 86. In the embodiment shown in FIG. 18C, the sidewall surface of the lower portion 86L of the layer contact via structures 86 contacts a sidewall of the first dielectric fin 84F1.

Referring to FIG. 18D, a first alternative embodiment of the exemplary structure is illustrated after processing steps that correspond to the processing steps described with reference to FIGS. 18A-18C. The first alternative embodiment of the exemplary structure illustrated in FIG. 18D can be derived from the alternative embodiment of the exemplary structure illustrated in FIG. 14H by performing the processing steps described with reference to FIGS. 15-18C. In the embodiment shown in FIG. 18D, the sidewall surface of the lower portion 86L of the layer contact via structures 86 does not contact a sidewall of the first dielectric fin 84F1.

Referring to FIG. 18E, a second alternative embodiment of the exemplary structure is illustrated after processing steps that correspond to the processing steps described with reference to FIGS. 18A-18C. The second alternative embodiment of the exemplary structure illustrated in FIG. 18E can be derived from the alternative embodiment of the exemplary structure illustrated in FIG. 141 by performing the processing steps described with reference to FIGS. 15-18C. In the embodiment shown in FIG. 18E, the sidewall surface of the lower portion 86L of the layer contact via structures 86 does not contact a sidewall of the first dielectric fin 84F1.

Referring collectively to FIGS. 1-18E and according to various embodiments of the present disclosure, a memory device comprises: an alternating stack (32, 46) of insulating layers 32 and electrically conductive layers 46, wherein the alternating stack (32, 46) comprises a staircase region 200 in which lateral extents of the electrically conductive layers 46 vary with a vertical distance from a horizontal plane including a bottommost surface of the alternating stack (32, 46); a vertical stack of memory elements (such as portions of a memory material layer 54) vertically extending through the alternating stack (32, 46), wherein the memory elements are located at levels of the electrically conductive layers 46; and a contact assembly (84, 86) comprising a layer contact via structure 86 comprising an upper portion 86U and a lower portion 86L having a smaller width (e.g., smaller diameter) than the upper portion 86U, wherein the upper portion 86L contacts a sidewall of an opening through a first electrically conductive layer 461 of the electrically conductive layers 46 in the staircase region 200, and the lower portion 86L extends below the first electrically conductive layer 461; and a dielectric base 84 comprising a dielectric material and contacting an additional electrically conductive layer (462 and/or 463) of the electrically conductive layers 46, wherein the additional electrically conductive layer underlies the first electrically conductive layer 461.

In one embodiment, the memory device further comprises a memory opening 49 vertically extending through the alternating stack (32, 46); and a memory opening fill structure 58 located in the memory opening 49. The memory opening fill structure 58 comprises a vertical semiconductor channel 60 and a memory film 50, and the memory elements comprise portions of the memory film 50 located at the levels of the electrically conductive layers 46.

In one embodiment, the layer contact via structure 86 further comprises a horizontal step 86H located between the upper portion 86U and the lower portion 86L.

In one embodiment, a cylindrical sidewall surface segment of the upper portion 86U of the layer contact via structure 86 contacts a cylindrical sidewall surface of the opening 471 in the first electrically conductive layer 461. The lower portion 86L contacts a first cylindrical sidewall surface segment of a cylindrical opening through a first insulating layer 321 of the insulating layers 32 which overlies the additional electrically conductive layer (462 and/or 463) and underlies the first electrically conductive layer 461.

In one embodiment, the dielectric base 84 comprises a cylindrical sidewall surface segment that contacts a second cylindrical sidewall surface segment of the cylindrical opening through the first insulating layer 321.

In one embodiment, a contact surface between dielectric base 84 and the layer contact via structure 86 has a lesser area than an area enclosed by a bottom periphery of the cylindrical surface of the opening 471 in the first electrically conductive layer 461.

In one embodiment, the dielectric base 84 comprises: a dielectric pillar portion 84P that contacts a bottommost surface of the lower portion 86L of the layer contact via structure 86; and a first dielectric fin 84F2 that laterally protrudes from the dielectric pillar portion 84P and having a lesser vertical extent than the dielectric pillar portion 84P. In one embodiment, the first dielectric fin 84F2 wider than the lower portion 86L of the layer contact via structure 86.

In one embodiment, the first dielectric fin 84F2 is located within an opening through the additional electrically conductive layer 463. In one embodiment, the first dielectric fin 84F2 comprises a cylindrical sidewall surface that contacts a cylindrical sidewall surface of the opening through the additional electrically conductive layer 463. In one embodiment, the dielectric pillar portion 84P comprises: a first cylindrical sidewall surface that contacts a cylindrical surface segment of an opening through a first insulating layer 321 of the insulating layers 32 that is located between the first electrically conductive layer 461 and the additional electrically conductive layer (462 and/or 463); and a second cylindrical sidewall surface that contacts a cylindrical sidewall surface of an opening through a second insulating layer 322 of the insulating layers 32 that is located below the additional electrically conductive layer.

In one embodiment shown in FIG. 18C, a second dielectric fin 84F1 overlies the first dielectric fin 84F2 and is vertically separated from the dielectric base 84. The additional electrically conductive layer comprises a third electrically conductive layer 463; and the second dielectric fin 84F1 comprises a cylindrical sidewall that contacts a cylindrical sidewall of an opening through a second electrically conductive layer 462 that underlies the first electrically conductive layer 461 and overlies the third electrically conductive layer 463. A bottommost surface of the dielectric base 84 is located within a horizontal plane including a bottom surface of the third electrically conductive layer 463.

In another embodiment shown in FIG. 18D, the dielectric base 84 further comprises a second dielectric fin 84F1 that laterally protrudes from the dielectric pillar portion 84P and overlies the first dielectric fin 84F2. In one embodiment, the additional electrically conductive layer comprises a third electrically conductive layer 463; and the second dielectric fin 84F2 comprises a cylindrical sidewall surface that contacts a cylindrical sidewall surface of an opening through a third electrically conductive layer 463 that underlies the second electrically conductive layer 462. A bottommost surface of the dielectric base 84 is located within a horizontal plane including a bottom surface of the third electrically conductive layer 463.

In one embodiment, a retro-stepped dielectric material portion 65 overlies the staircase region 200 of the alternating stack and has a stepped bottom surface that contains horizontally-extending surface segments that are vertically offset from each other and adjoined to each other by vertically-extending surface segments. The layer contact via structure 86 vertically extends through an opening in one of the horizontally-extending surface segments of the retro-stepped dielectric material portion 65.

The embodiments of the present disclosure reduce the risk of the layer contact via structures 86 shorting two vertically adjacent electrically conductive layers 46 by adding the dielectric base 84 and/or the dielectric fins 84F below the layer contact via structure 86.

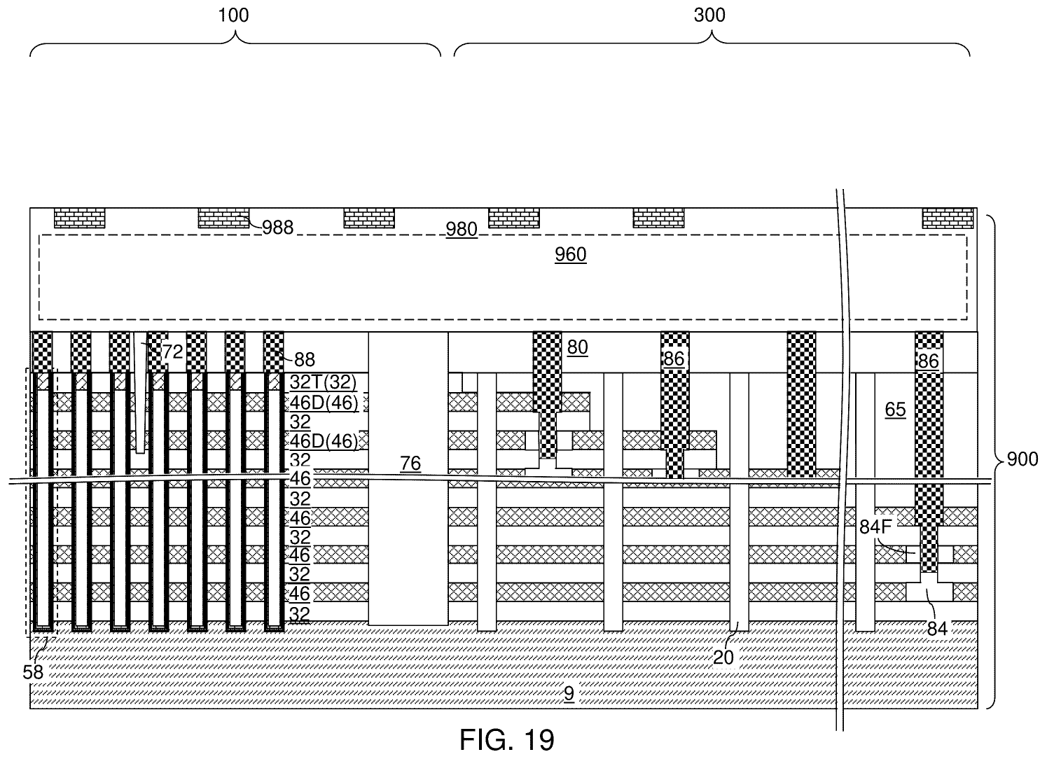

Referring to FIG. 19, additional dielectric material layers and additional metal interconnect structures can be formed over the contact-level dielectric layer 80. The additional dielectric material layers may include at least one via-level dielectric layer, at least one additional line-level dielectric layer, and/or at least one additional line-and-via-level dielectric layer. The additional metal interconnect structures may comprise metal via structures, metal line structures, and/or integrated metal line-and-via structures. The additional dielectric material layers that are formed above the contact-level dielectric layer 80 are herein referred to as memory-side dielectric material layers 960. The additional metal interconnect structures are collectively referred to as memory-side metal interconnect structures 980. The memory-side dielectric material layers 960 comprise a bit-line-level dielectric material layer embedding bit lines, which are a subset of the memory-side metal interconnect structures 980.

Metal bonding pads, which are herein referred to as memory-side bonding pads 988, may be formed at the topmost level of the memory-side dielectric material layers 960. The memory-side bonding pads 988 may be electrically connected to the memory-side metal interconnect structures 980 and various nodes of the three-dimensional memory array including the electrically conductive layers 46 and the memory opening fill structures 58. A memory die 900 can thus be provided.

The memory-side dielectric material layers 960 are formed over the alternating stacks (32, 46). The memory-side metal interconnect structures 980 are embedded in the memory-side dielectric material layers 960. The memory-side bonding pads 988 can be embedded within the memory-side dielectric material layers 960, and specifically, within the topmost layer among the memory-side dielectric material layers 960. The memory-side bonding pads 988 can be electrically connected to the memory-side metal interconnect structures 980.

In one embodiment, the memory die 900 may comprise: a three-dimensional memory array comprising an alternating stack (32, 46) of insulating layers 32 and electrically conductive layers 46, a two-dimensional array of memory openings 49 vertically extending through the alternating stack (32, 46), and a two-dimensional array of memory opening fill structures 58 located in the two-dimensional array of memory openings 49 and comprising a respective vertical stack of memory elements and a respective vertical semiconductor channel 60; and a two-dimensional array of contact via structures (such as the drain contact via structures 88) overlying the three-dimensional memory array and electrically connected to a respective one of the vertical semiconductor channels 60.

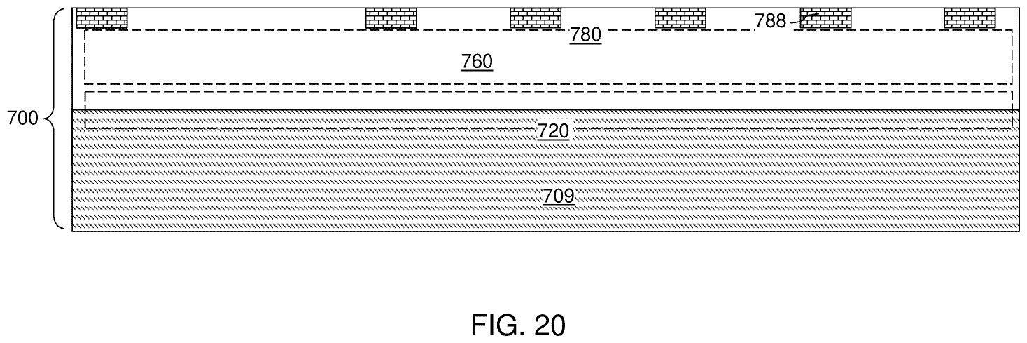

Referring to FIG. 20, a logic die 700 can be provided. The logic die 700 includes a logic-side substrate 709, a peripheral circuit 720 located on the logic-side substrate 709 and comprising logic-side semiconductor devices (such as field effect transistors), logic-side metal interconnect structures 780 embedded within logic-side dielectric material layers 760, and logic-side bonding pads 788. The peripheral circuit 720 can be configured to control operation of the memory array within the memory die 900. Specifically, the peripheral circuit 720 can be configured to drive various electrical components within the memory array including, but not limited to, the electrically conductive layers 46, the drain regions 63, and a source contact structure to be subsequently formed. The peripheral circuit 720 can be configured to control operation of the vertical stack of memory elements in the memory array in the memory die 900.

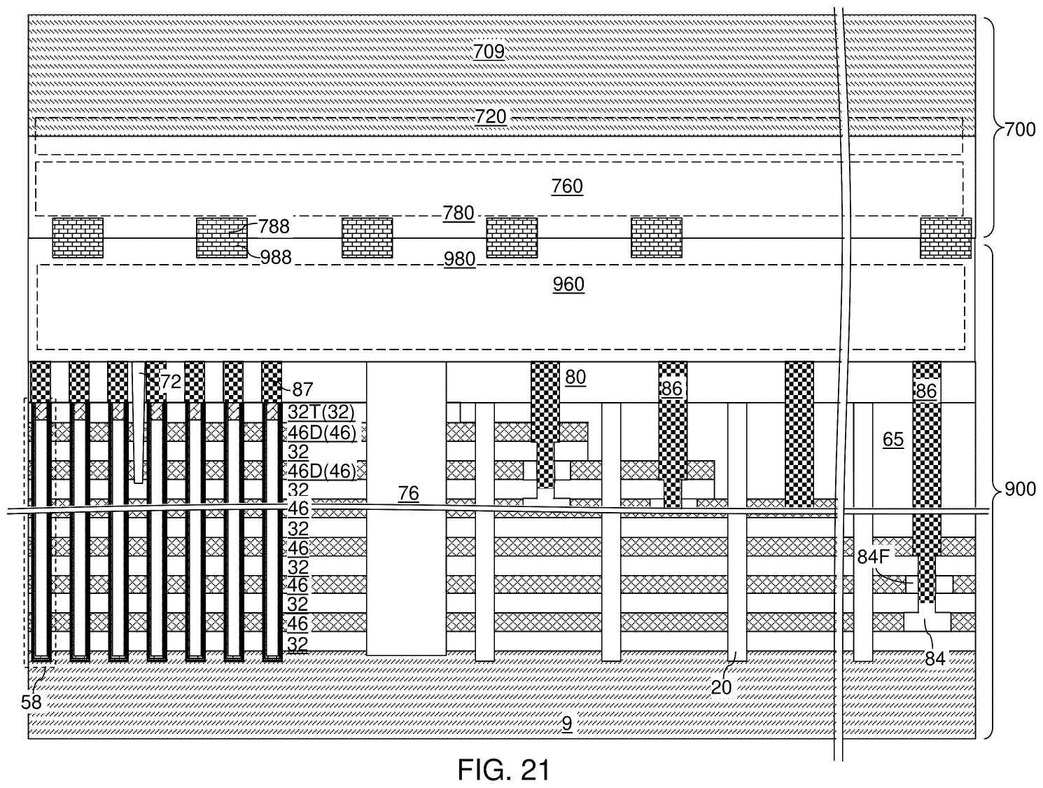

Referring to FIG. 21, the logic die 700 can be attached to the memory die 900, for example, by bonding the logic-side bonding pads 788 to the memory-side bonding pads 988 at a bonding interface. The bonding between the memory die 900 and the logic die 700 may be performed employing a wafer-to-wafer bonding process in which a two-dimensional array of memory dies 900 is bonded to a two-dimensional array of logic dies 700, by a die-to-bonding process, or by a die-to-die bonding process. The logic-side bonding pads 788 within each logic die 700 can be bonded to the memory-side bonding pads 988 within a respective memory die 900.

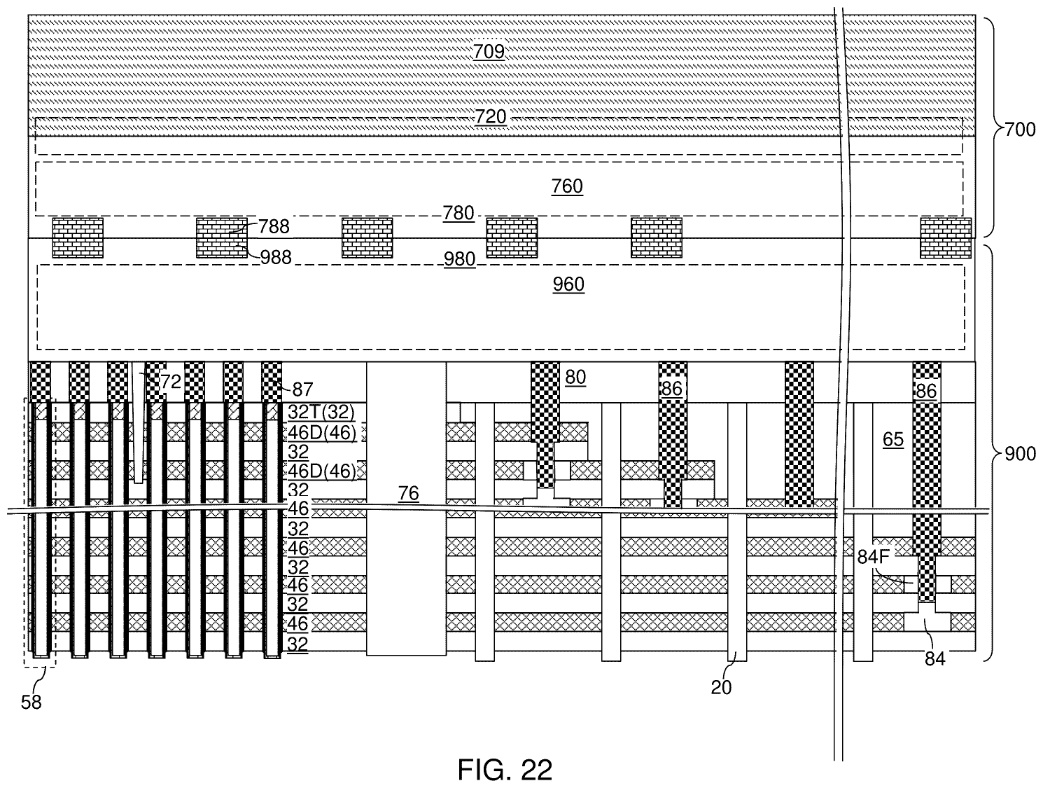

Referring to FIG. 22, the carrier substrate 9 can be removed, for example, by grinding, polishing, cleaving, an isotropic etch process, an anisotropic etch process, and/or a combination thereof. If a chemical mechanical polishing process or an etch process is employed as a terminal step for removing the carrier substrate 9, the bottommost insulating layer 32B may be employed as a polish stop or etch stop, respectively.

In one embodiment, at least a terminal step of at least one removal process that is employed to remove the carrier substrate 9 may comprise a selective wet etch process that etches the material of the carrier substrate 9 (such as a semiconductor material of the carrier substrate 9) selective to dielectric materials of the memory films 50. In an illustrative example, if the carrier substrate 9 comprises a semiconductor material, the terminal step of the at least one removal process may comprise a wet etch process using hot trimethyl-2 hydroxyethyl ammonium hydroxide (“hot TMY”) or tetramethyl ammonium hydroxide (TMAH). The entirety of the carrier substrate 9 can be removed by the selective wet etch process. Backside end surfaces of the support pillar structures 20 can be physically exposed upon removal of the carrier substrate 9.

A sequence of wet etch steps can be performed to sequentially remove portions of the memory film 50 that are exposed on the backside of the alternating stack (32, 46). For example, the inner blocking dielectric layer 52, the memory material layer 54, and the optional dielectric liner 56 (which may be, for example, a tunneling dielectric layer) of each memory film 50 can be removed from a region that is more distal from the bonding interface between the memory die 900 and the logic die 700 than a physically exposed planar surface of the bottommost insulating layer 32B is from the bonding interface. The blocking dielectric layer 52, the memory material layer 54, and the optional dielectric liner 56 (which may be, for example, a tunneling dielectric layer) of each memory film 50 can be removed from below the horizontal plane including the bottom surface of the bottommost insulating layer 32B.

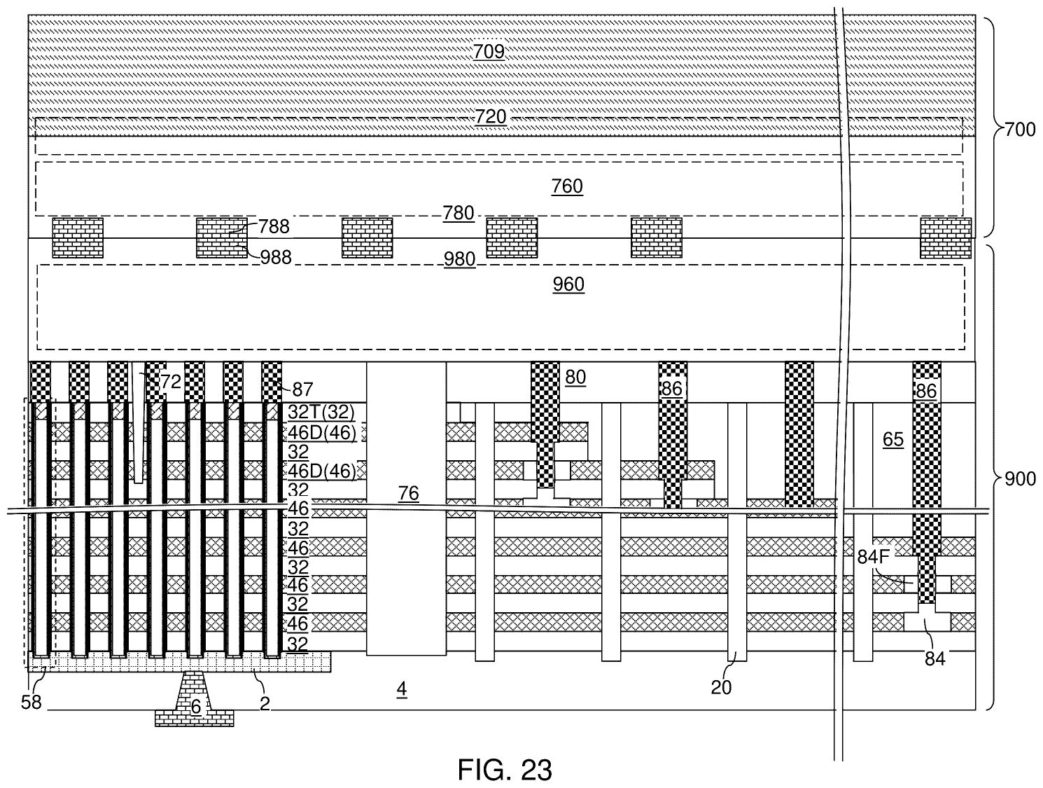

Referring to FIG. 23, source structures 2 (such as at least one heavily doped semiconductor and/or metallic source layer), a backside dielectric layer 5, and backside contact via structures 6 can be subsequently formed.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph of in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A memory device, comprising:
an alternating stack of insulating layers and electrically conductive layers, wherein the alternating stack comprises a staircase region in which lateral extents of the electrically conductive layers vary with a vertical distance from a horizontal plane including a bottommost surface of the alternating stack;
a vertical stack of memory elements vertically extending through the alternating stack, wherein the memory elements are located at levels of the electrically conductive layers; and
a contact assembly comprising:
a layer contact via structure comprising an upper portion and a lower portion having a smaller width than the upper portion, wherein the upper portion contacts a sidewall of an opening through a first electrically conductive layer of the electrically conductive layers in the staircase region, and the lower portion extends below the first electrically conductive layer; and
a dielectric base comprising a dielectric material and contacting an additional electrically conductive layer of the electrically conductive layers, wherein the additional electrically conductive layer underlies the first electrically conductive layer.

2. The memory device of claim 1, further comprising:
a memory opening vertically extending through the alternating stack; and
a memory opening fill structure located in the memory opening, wherein the memory opening fill structure comprises a vertical semiconductor channel and a memory film, wherein the memory elements comprise portions of the memory film located at the levels of the electrically conductive layers.

3. The memory device of claim 2, wherein the layer contact via structure further comprises a horizontal step located between the upper portion and the lower portion.

4. The memory device of claim 3, wherein:
wherein a cylindrical sidewall surface segment of the upper portion of the layer contact via structure contacts a cylindrical sidewall surface of the opening in the first electrically conductive layer; and
the lower portion contacts a first cylindrical sidewall surface segment of a cylindrical opening through a first insulating layer of the insulating layers which overlies the additional electrically conductive layer and underlies the first electrically conductive layer.

5. The memory device of claim 4, wherein the dielectric base comprises a cylindrical sidewall surface segment that contacts a second cylindrical sidewall surface segment of the cylindrical opening through the first insulating layer.

6. The memory device of claim 1, wherein the dielectric base comprises:
a dielectric pillar portion that contacts a bottommost surface of the lower portion of the layer contact via structure; and
a first dielectric fin that laterally protrudes from the dielectric pillar portion and having a lesser vertical extent than the dielectric pillar portion.

7. The memory device of claim 6, wherein the first dielectric fin is wider than the lower portion of the layer contact via structure.

8. The memory device of claim 6, wherein:
the first dielectric fin is located within an opening through the additional electrically conductive layer; and
the first dielectric fin comprises a cylindrical sidewall surface that contacts a cylindrical sidewall surface of the opening through the additional electrically conductive layer.

9. The memory device of claim 8, wherein the dielectric pillar portion comprises:
a first cylindrical sidewall surface that contacts a cylindrical sidewall surface segment of an opening through a first insulating layer of the insulating layers that is located between the first electrically conductive layer and the additional electrically conductive layer; and
a second cylindrical sidewall surface that contacts a cylindrical sidewall surface of an opening through a second insulating layer of the insulating layers that is located below the additional electrically conductive layer.

10. The memory device of claim 9, further comprising a second dielectric fin that overlies the first dielectric fin and is vertically separated from the dielectric base.

11. The memory device of claim 10, wherein:
the additional electrically conductive layer comprises a third electrically conductive layer;
the second dielectric fin comprises a cylindrical sidewall surface that contacts a cylindrical sidewall surface of an opening through a second electrically conductive layer that underlies the first electrically conductive layer and overlies the third electrically conductive layer.

12. The memory device of claim 11, wherein a bottommost surface of the dielectric base is located within a horizontal plane including a bottom surface of the third electrically conductive layer.

13. The memory device of claim 9, wherein the dielectric base further comprises a second dielectric fin that laterally protrudes from the dielectric pillar portion and overlies the first dielectric fin.

14. The memory device of claim 13, wherein:
the additional electrically conductive layer comprises a third electrically conductive layer;
the second dielectric fin comprises a cylindrical sidewall surface that contacts a cylindrical sidewall surface of an opening through a second electrically conductive layer that underlies the first electrically conductive layer and overlies the third electrically conductive layer; and
a bottommost surface of the dielectric base is located within a horizontal plane including a bottom surface of the third electrically conductive layer.

15. The memory device of claim 1, further comprising a retro-stepped dielectric material portion overlying the staircase region of the alternating stack and having a stepped bottom surface that contains horizontally-extending surface segments that are vertically offset from each other and adjoined to each other by vertically-extending surface segments, wherein the layer contact via structure vertically extending through an opening in one of the horizontally-extending surface segments.

16. A method, comprising:
forming an alternating stack of insulating layers and spacer material layers over a substrate, wherein the spacer material layers are formed as, or are subsequently replaced with, electrically conductive layers;
forming stepped surfaces by patterning the alternating stack;
forming a retro-stepped dielectric material portion overlying the stepped surfaces;
forming a layer contact via cavity through the retro-stepped dielectric material portion such that the layer contact via cavity vertically extends through a horizontally-extending surface segment of a stepped bottom surface of the retro-stepped dielectric material portion and through a first electrically conductive layer of the electrically conductive layers;
forming a sacrificial tubular spacer in a peripheral volume of the layer contact via cavity;
vertically extending the layer contact via cavity, wherein a vertically-extended portion of the layer contact via cavity extends at least through a first insulating layer of the insulating layers and into a second electrically conductive layer of the electrically conductive layers which underlies the first electrically conductive layer;
performing a first isotropic etch process that etches a material of the electrically conductive layers selective to a material of the insulating layers to form a first fin cavity in a volume from which an annular portion of the second electrically conductive layer is removed;
forming a dielectric base within a volume of the first fin cavity and a portion of the vertically-extended portion of the layer contact via cavity; and
forming a layer contact via structure over the dielectric base on a physically exposed surface of the first electrically conductive layer.

17. The method of claim 16, wherein:
a cylindrical sidewall surface of the first electrically conductive layer is exposed upon formation of the layer contact via cavity through the first electrically conductive layer; and
the layer contact via structure is formed directly on the cylindrical sidewall surface of the first electrically conductive layer.

18. The method of claim 16, wherein the dielectric base is formed by:
conformally depositing a dielectric material layer in layer contact via cavity and the first fin cavity to completely fill the first fin cavity without completely filling the layer contact via cavity; and
performing a second isotropic etch process that etches an upper portion of the dielectric material layer, wherein a remaining portion of the dielectric material layer comprises the dielectric base and a dielectric fin which is located above the dielectric base and is vertically separated from the dielectric base.

19. The method of claim 16, wherein the dielectric base is formed by:
conformally depositing a dielectric material layer in layer contact via cavity, the first fin cavity and a second fin cavity overlying the first fin cavity to completely fill the first fin cavity and the second fin cavity without completely filling the layer contact via cavity; and
performing a second etch process that etches an upper portion of the dielectric material layer, wherein a remaining portion of the dielectric material layer comprises the dielectric base.

20. The method of claim 16, further comprising:
forming a memory opening through the alternating stack; and
forming a memory opening fill structure in the memory opening, wherein the memory opening fill structure comprises a vertical semiconductor channel and vertical stack of memory elements that are located at levels of the spacer material layers.
